(19) United States
(12) Patent Application Publication
(10) Pub. No.: US 2023/0306252 A1
(43) Pub. Date: Sep. 28, 2023

(54) CALIBRATING ANALOG RESISTIVE PROCESSING UNIT SYSTEM

(71) Applicant: International Business Machines Corporation, Armonk, NY (US)

(72) Inventors: Stefano Ambrogio, San Jose, CA (US); Pritish Narayanan, San Jose, CA (US); Geoffrey Burr, Cupertino, CA (US)

(21) Appl. No.: 17/704,515

(22) Filed: Mar. 25, 2022

(51) Int. Cl. G06N 3/063; G11C 11/54; G06N 3/04; G06N 3/08; G06F 17/16; G06F 17/12

(52) U.S. Cl. CPC G06N 3/0635; G11C 11/54; G06N 3/04; G06N 3/08; G06F 17/16; G06F 17/12

(57) ABSTRACT

A system comprises a processor, and a resistive processing unit (RPU) array. The RPU array comprises an array of cells which respectively comprise resistive memory devices that are programable to store weight values. The processor is configured to obtain a matrix comprising target weight values, program cells of the array of cells to store weight values in the RPU array, which correspond to respective target weight values of the matrix, and perform a calibration process to calibrate the RPU array. The calibration process comprises iteratively adjusting the target weight values of the matrix, and reprogramming the stored weight values of the matrix in the RPU array based on the respective adjusted target weight values, to reduce a variation between output lines of the RPU array with respect to multiply-and-accumulate distribution data that is generated and output from respective output lines of the RPU array during the calibration process.

### BACKGROUND

This disclosure relates generally to analog non-volatile resistive memory systems for neuromorphic computing, and techniques for calibrating analog resistive processing unit systems (e.g., analog resistive memory crossbar arrays) for neuromorphic computing and other hardware accelerated computing applications. Information processing systems and artificial intelligence (AI) systems such as neuromorphic computing systems and artificial neural network systems are utilized in various applications such as machine learning and inference processing for cognitive recognition, etc. Such systems are hardware-based systems that generally include a large number of highly interconnected processing elements (referred to as “artificial neurons”) which operate in parallel to perform various types of computations. The artificial neurons (e.g., pre-synaptic neurons and post-synaptic neurons) are connected using artificial synaptic devices which provide synaptic weights that represent connection strengths between the artificial neurons. The synaptic weights can be implemented using an analog resistive memory crossbar array, e.g., an analog resistive processing unit (RPU) crossbar array comprising an array of RPU cells having tunable resistive memory devices (e.g., tunable conductance), wherein the conductance states of the RPU cells are encoded or otherwise mapped to the synaptic weights. Furthermore, in an artificial neural network, each artificial neuron implements an activation function which is configured to, e.g., transform the inputs to the artificial neuron into an output value or “activation” of the given artificial neuron.

For applications such as neuromorphic and AI computing applications, vector-matrix multiplication operations (or matrix-vector multiplication operations) can be performed in analog hardware by programming an analog RPU crossbar array is to store a matrix of weights W that are encoded in the conductance values of analog RPU cells (e.g., non-volatile resistive memory devices) of the RPU crossbar array, and applying input voltages (e.g., excitation input vector x) in parallel to multiple rows (or columns) of the RPU crossbar array to perform multiply-and-accumulate (MAC) operations across the entire matrix of stored weights. The MAC results that are generated at the output of the columns (or rows) of the RPU crossbar array represent an output vector y, wherein y=Wx.

Due to non-idealities of the analog RPU hardware, however, the actual output vector y may be different from the excepted (target) output vector due to hardware computation errors that arise due to the non-idealities of the analog RPU hardware, i.e., y=Wx+error. Such error can arise due to mismatches, offsets, leakage, parasitic resistances and capacitances, etc., in the analog RPU hardware. For example, the analog RPU hardware can exhibit column-to-column variations (or row-to-row variations) which can result in significant errors of the MAC results that are obtained by performing the hardware matrix-vector multiplication operations, e.g., the columns of the RPU array exhibit different offsets, slopes, and/or spread in the MAC results that are output from the columns.

### SUMMARY

Exemplary embodiments of the disclosure provide techniques for calibrating analog resistive processing unit systems (e.g., analog resistive processing unit arrays). In an exemplary embodiment, a system comprises a processor, and a resistive processing unit array coupled to the processor. The resistive processing unit array comprises an array of cells which respectively comprises resistive memory devices that are programable to store weight values. The processor is configured to obtain a matrix comprising target weight values, program cells of the array of cells to store weight values in the resistive processing unit array, which correspond to respective target weight values of the matrix, and perform a calibration process to calibrate the resistive processing unit array. The calibration process comprises iteratively adjusting the target weight values of the matrix, and reprogramming the stored weight values of the matrix in the resistive processing unit array based on the respective adjusted target weight values, to reduce a variation between output lines of the resistive processing unit array with respect to multiply-and-accumulate distribution data that is generated and output from respective output lines of the resistive processing unit array during the calibration process.

Advantageously, in one or more illustrative embodiments, the calibration process is implemented in an analog domain by iteratively adjusting the stored weight values to reduce variations in the output lines of the resistive processing unit array (e.g., analog resistive processing unit crossbar array), which can result in significant errors of the multiply-and-accumulate results that are obtained when performing, e.g., hardware matrix-vector multiplication operations. Further, the calibration process may be configured to reduce line-to-line variations such as offset variations, slope variations, and/or spread variations in the multiply-and-accumulate data output from the different output lines of the resistive processing unit array. Still further, the analog calibration may eliminate the need to configure and utilize digital hardware and circuitry (e.g., peripheral digital circuitry of an analog resistive processing unit crossbar array) to implement digital calibration methods which require increased power consumption/utilization by, e.g., the peripheral digital circuitry of the analog resistive processing unit crossbar array to perform such digital calibration.

In another exemplary embodiment, a system comprises a processor, and a resistive processing unit array coupled to the processor. The resistive processing unit array comprises an array of cells which respectively comprise resistive memory devices that are programable to store weight values. The processor is configured to obtain a matrix comprising target weight values, program cells of the array of cells to store weight values, in the resistive processing unit array, which correspond to respective target weight values of the matrix, and perform a calibration process to calibrate the resistive processing unit array. The calibration process comprises a first calibration process to iteratively adjust the target weight values of the matrix, and reprogram the stored weight values of the matrix in the resistive processing unit array based on the respective adjusted target weight values, to reduce an offset variation between output lines of the resistive processing unit array with respect to multiply-and-accumulate distribution data and to reduce a spread of the multiply-and-accumulate distribution data, which is generated and output from respective output lines of the resistive processing unit array during the first calibration process. A second calibration process is performed subsequent to the first calibration process, to scale the adjusted target weight values of the output lines, which exist at a completion of the first calibration process, by respective weight scaling factors, and reprogram the stored weight values of the output lines of the resistive processing unit array based on the scaled target weight values to reduce a slope variation between the output lines of the resistive processing unit array with respect to multiply-and-accumulate distribution data which is generated and output from the respective output lines of the resistive processing unit array.

In another exemplary embodiment, the calibration process further comprises a third calibration process, which is performed subsequent to the second calibration process, to iteratively adjust one or more target bias weight values, which correspond to one or more stored bias weights of one or more of the output lines, and reprogram the one or more stored bias weights of the one or more output lines, based on the adjusted target bias weight values, to reduce a residual offset variation between the output lines of the resistive processing unit array with respect to multiply-and-accumulate distribution data which is generated and output from respective output lines of the resistive processing unit array during the third calibration process.

Other embodiments will be described in the following detailed description of exemplary embodiments, which is to be read in conjunction with the accompanying figures.

### BRIEF DESCRIPTION OF THE DRAWINGS

FIGS. 1A and 1B schematically illustrate a computing system which is configured to calibrate analog resistive memory crossbar arrays, according to an exemplary embodiment of the disclosure.

FIG. 2 schematically illustrates a resistive processing unit compute node comprising a plurality of resistive processing unit chips, which can be utilized to implement the computing system of FIG. 1, according to an exemplary embodiment of the disclosure.

FIG. 3 schematically illustrates a resistive processing unit system which is configured to implement an artificial neural network comprising artificial neurons and artificial synaptic device arrays, according to an exemplary embodiment of the disclosure.

FIG. 4 schematically illustrates a method for configuring a resistive processing unit system to implement an artificial neural network comprising artificial neurons which comprise analog hardware-implemented activation function circuitry, according to an exemplary embodiment of the disclosure.

FIG. 5A graphically illustrates a rectified linear unit (ReLU) activation function which can be implemented in hardware according to an exemplary embodiment of the disclosure.

FIG. 5B graphically illustrates a clamped ReLU activation function which can be implemented in hardware according to an exemplary embodiment of the disclosure.

FIG. 5C graphically illustrates a hard sigmoid activation function which can be implemented in hardware according to an exemplary embodiment of the disclosure.

FIG. 5D graphically illustrates a hard hyperbolic tangent (tanh) activation function which can be implemented in hardware according to an exemplary embodiment of the disclosure.

FIG. 6 schematically illustrates activation function circuitry which is configurable to implement a hardware activation function, according to an exemplary embodiment of the invention.

FIG. 7A schematically illustrates an exemplary configuration of the hardware system of FIG. 6 to implement a ReLU activation function, according to an exemplary embodiment of the disclosure.

FIG. 7B schematically illustrates an exemplary configuration of the hardware system of FIG. 6 to implement a hard sigmoid activation function, according to an exemplary embodiment of the disclosure.

FIG. 7C schematically illustrates an exemplary configuration of the hardware system of FIG. 6 to implement a linear activation function, according to an exemplary embodiment of the disclosure.

FIG. 8 graphically illustrates various line-to-line variations of an analog resistive memory crossbar array which can lead to degraded multiply-and-accumulate (MAC) computations, according to an exemplary embodiment of the disclosure.

FIGS. 9A and 9B schematically illustrate a process of adjusting a zero vector and reprograming weights to compensate for column-to-column offset variation of a given analog resistive memory crossbar array, according to an exemplary embodiment of the disclosure.

FIG. 10 is a flow diagram of a method for calibrating an analog crossbar array, according to an exemplary embodiment of the disclosure.

FIG. 11 is a flow diagram of a method for calibrating an analog crossbar array, according to another exemplary embodiment of the disclosure.

FIG. 12 is a flow diagram of a method for calibrating an analog crossbar array, according to another exemplary embodiment of the disclosure.

FIG. 13 schematically illustrates an exemplary architecture of a computing node which can host the computing system of FIG. 1, according to an exemplary embodiment of the disclosure.

FIG. 14 depicts a cloud computing environment according to an exemplary embodiment of the disclosure.

FIG. 15 depicts abstraction model layers according to an exemplary embodiment of the disclosure.

### DETAILED DESCRIPTION

Exemplary embodiments of the disclosure will now be described in further detail with regard to systems and methods for calibrating analog resistive memory crossbar arrays for, e.g., neuromorphic computing systems. It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

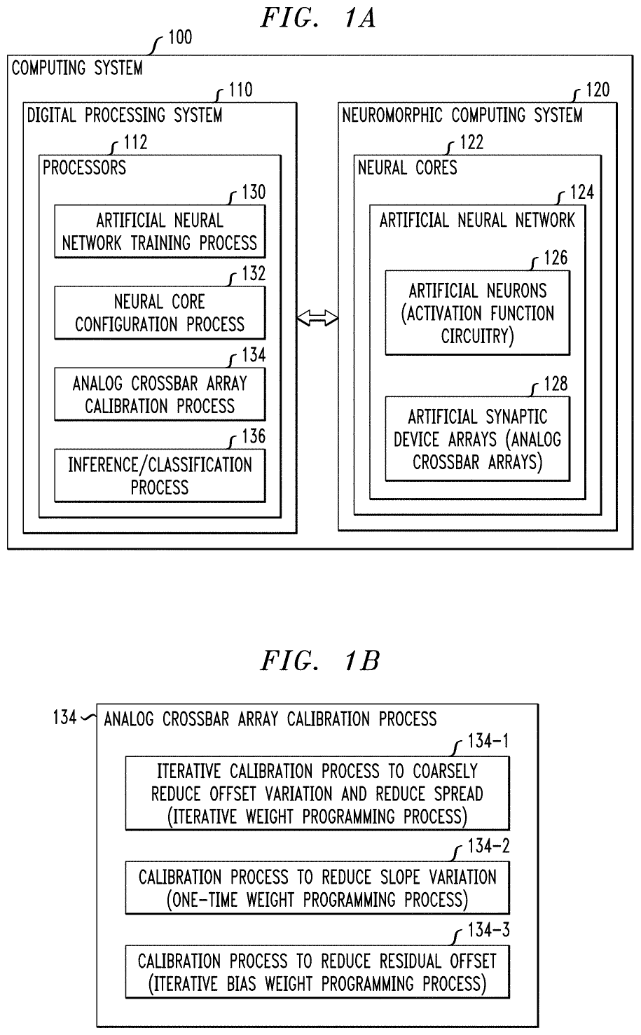

FIGS. 1A and 1B schematically illustrate a computing system which is configured to calibrate analog resistive memory crossbar arrays, according to an exemplary embodiment of the disclosure. In particular, FIG. 1A schematically illustrates a computing system 100 which comprises a digital processing system 110, and a neuromorphic computing system 120. The digital processing system 110 comprises a plurality of processors 112. The neuromorphic computing system 120 comprises one or more neural cores 122. In some embodiments, the neural cores 122 are configured to implement an artificial neural network 124 which comprises multiple layers of artificial neurons 126 (alternatively referred to as nodes 126) which process information in the artificial neural network 124, and artificial synaptic device arrays 128 which provide connections between the artificial neuron layers to transfer electrical signals between the artificial neurons 126 using analog circuitry (e.g., analog resistive memory crossbar arrays).

In some embodiments, the neuromorphic computing system 120 comprises an RPU system in which the neural cores 122 are implemented using one or more RPU compute nodes and associated RPU devices (e.g., RPU accelerator chips), which comprise analog RPU crossbar arrays. The neural cores 122 are configured to support hardware accelerated computing (in the analog domain) of numerical operations (e.g., kernel functions) such as, e.g., matrix-vector multiplication (MVM) operations, vector-matrix multiplication (VMM) operations, matrix-matrix multiplication operations, vector-vector outer product operations (e.g., outer product rank 1 matrix weight updates), etc.

The digital processing system 110 performs various processes through the execution of program code by the processors 112 to implement neuromorphic computing applications, AI computing applications, and other applications which are built on kernel functions such as vector-matrix multiplication operations, matrix-vector multiplication operations, vector-vector outer product operations, etc., which can be performed in the analog domain using the neural cores 122. The processors 112 may include various types of processors that perform processing functions based on software, hardware, firmware, etc. For example, the processors 112 may comprise any number and combination of CPUs, ASICs, FPGAs, GPUs, Microprocessing Units (MPUs), deep learning accelerator (DLA), artificial intelligence (AI) accelerators, and other types of specialized processors or coprocessors that are configured to execute one or more fixed functions. In some embodiments, the digital processing system 110 is implemented on one compute node, while in other embodiments, the digital processing system 110 is implemented on multiple compute nodes.

In some embodiments, as shown in FIG. 1A, the digital processing system 110 performs various processes including, but not limited to, an artificial neural network training process 130, a neural core configuration process 132, an analog crossbar array calibration process 134, and an inference/classification process 136. Further, in some embodiments, as shown in FIG. 1B, the analog crossbar array calibration process 134 comprises a first calibration process 134-1, a second calibration process 134-2, and a third calibration process 134-3. As explained in further detail below, the analog crossbar array calibration process 134 implements methods for calibrating the analog RPU hardware of the neural cores 122 to reduce hardware computation errors that arise due to the programming errors and non-idealities of the analog RPU hardware.

In some embodiments, the artificial neural network training process 130 implements methods for training an artificial neural network model in the digital domain. The artificial neural network model can be any type of neural network including, but not limited to, a feed-forward neural network (e.g., a Deep Neural Network (DNN), a Convolutional Neural Network (CNN), etc.), a Recurrent Neural Network (RNN) (e.g., a Long Short-Term Memory (LSTM) neural network), etc. In general, an artificial neural network comprises a plurality of layers (neuron layers), wherein each layer comprises multiple neurons. The neuron layers include an input layer, an output layer, and one or more hidden model layers between the input and output layers, wherein the number of neuron layer and configuration of the neuron layers (e.g., number of constituent artificial neurons) will vary depending on the type of neural network that is implemented.

In an artificial neural network, each neuron layer is connected to another neuron layer using a synaptic weight matrix which comprises synaptic weights that represent connection strengths between the neurons in one layer with the neurons in another layer. The input layer of an artificial neural network comprises input neurons which receive data that is input to the artificial neural network for further processing by one or more subsequent hidden model layers of artificial neurons. The hidden layers perform various computations, depending on type and framework of the artificial neural network. The output layer (e.g., classification layer) produces the output results (e.g., classification/predication results) for the given input data. Depending on the type of artificial neural network, the layers of the artificial neural network can include, e.g., fully connected layers, activation layers, convolutional layers, pooling layers, normalization layers, etc.

Further, in an artificial neural network, each artificial neuron implements an activation function which defines an output of the neuron given an input or set of inputs to the neuron. For example, depending on the given application and the type of artificial neural network, the activation functions implemented by the neurons can include one or more types of non-linear activation functions including, but not limited to, a rectified linear unit (ReLU) activation function, a clamped ReLU activation function, a sigmoid activation function, a hyperbolic tangent (tanh) activation function, a softmax activation function, etc. In some embodiments, as explained in further detail below, the artificial neurons 126 of the hardware-implemented artificial neural network 124 comprise hardware-implemented activation functions that can be configured and calibrated to implement non-linear activation functions such as ReLU, clamped ReLU, hard sigmoid, and hard tanh activations, etc.

The type of artificial neural network training process 130 that is implemented in the digital domain depends on the type and size of the artificial neural network model to be trained. Model training methods generally include data parallel training methods (data parallelism) and model parallel training methods (model parallelism), which can be implemented in the digital domain using CPUs and accelerator devices such as GPU devices to control the model training process flow and to perform various computations for training an artificial neural network model in the digital domain. The training process involves, e.g., using a set of training data to train parameters (e.g., weights) of synaptic weight matrices of the artificial neural network model.

In general, in some embodiments, training an artificial neural network involves using a set of training data and performing a process of recursively adjusting the parameters/weights of the synaptic device arrays that connect the neuron layers, to fit the set of training data in order to maximize a likelihood function that minimizes error. The training process can be implemented using non-linear optimization techniques such as gradient-based techniques which utilize an error back-propagation process. For example, in some embodiments, a stochastic gradient descent (SGD) process is utilized to train artificial neural networks using the backpropagation method in which an error gradient with respect to each model parameter (e.g., weight) is calculated using the backpropagation algorithm.

As is known in the art, a backpropagation process comprises three repeating processes including (i) a forward process, (ii) a backward process, and (iii) a model parameter update process. During the training process, training data are randomly sampled into mini-batches, and the mini-batches are input to the artificial neural network to traverse the model in two phases: forward and backward passes. The forward pass processes input data in a forward direction (from the input layer to the output layer) through the layers of the network, and generates predictions and calculates errors between the predictions and the ground truth. The backward pass backpropagates errors in a backward direction (from the output layer to the input layer) through the artificial neural network to obtain gradients to update model weights. The forward and backward cycles mainly involve performing matrix-vector multiplication operations in forward and backward directions. The weight update involves performing incremental weight updates for weight values of the synaptic weight matrices of the artificial neural network being trained. The processing of a given mini-batch via the forward and backward phases is referred to as an iteration, and an epoch is defined as performing the forward-backward pass through an entire training dataset. The training process iterates multiple epochs until the model converges to given convergence criterion.

The neural core configuration process 132 implements methods for configuring the neural cores 122 of the neuromorphic computing system 120 to provide hardware-accelerated computational operations for a target application. For example, in some embodiments, for inference/classification processing and other AI applications, the neural core configuration process 132 can configure the neural cores 122 to implement an architecture of the artificial neural network which is initially trained in the digital domain by the artificial neural network training process 130. For example, in some embodiments, the neural core configuration process 132 communicates with a programming interface of the neuromorphic computing system 120 to (i) configure layers of artificial neurons 126 for the hardware-implemented artificial neural network 124, (ii) configure analog resistive memory cross bar arrays (e.g., analog RPU arrays) and associated peripheral circuitry to provide the artificial synaptic device arrays 128 that connect the layers of artificial neurons 126 of the artificial neural network 124, (iii) configure a routing system of the neuromorphic computing system 120 to enable communication between the analog processing elements and/or digital processing within a given neural core and/or between neural cores, etc.

More specifically, the neural core configuration process 132 can configure and calibrate the activation function circuitry of the artificial neurons 126 to implement different types of hardware-based activation functions, e.g., non-linear activation functions such as ReLU, clamped ReLU, hard sigmoid, and hard tanh activations, etc., depending on the given architecture of the artificial neural network 124. In addition, the neural core configuration process 132 comprises a weight tuning and programming process for programming and tuning the conductance values of resistive memory devices of the analog resistive memory crossbar arrays to store synaptic weight matrices in the artificial synaptic device arrays 128 which are configured to connect the layers of artificial neurons 126.

For example, in some embodiments, the artificial neural network training process 130 will generate a plurality of trained synaptic weight matrices for a given artificial neural network which is trained in the digital domain, wherein each synaptic weight matrix comprises a matrix of trained (target) weight values W_{T}. The trained synaptic weight matrices are stored in respective analog resistive memory crossbar arrays of the neural cores 122 to implement the artificial synaptic device arrays 128 of the artificial neural network 124. The neural core configuration process 132 implements methods to program/tune the conductance values of resistive memory devices of a given analog resistive memory crossbar array to store a matrix of programmed weight values W_{P} which corresponds to the trained (target) weight values W_{T} of a given synaptic weight matrix.

In other embodiments, the matrix of target weight values W_{T} can be a software matrix that is provided by any type of software application which utilizes matrices as computational objects to perform numerical operations for, e.g., solving linear equations, and performing other computations. For example, such applications include, but are not limited to, computing applications such as scientific computing applications, engineering applications, graphics rendering applications, signal processing applications, facial recognition applications, matrix diagonalization applications, a MIMO (Multiple-Input, Multiple-Output) system for wireless communications, cryptographic applications, etc. In this regard, a given software application executing on the digital processing system 110 can invoke the neural core configuration process 132 to configure an analog resistive memory crossbar array of a given neural core 122 to store the matrix of target weight values W_{T} in an RPU array to perform hardware accelerated computations (e.g., matrix-vector multiplication operations, vector-matrix multiplication operations, matrix-matrix multiplication operations, vector-vector outer product operations, etc.) using the stored matrix. In this manner, the neural core configuration process 132 will program a given analog resistive memory crossbar array to store a matrix of programmed weight values W_{P}, which corresponds to the matrix of target weight values W_{T} provided by the software application.

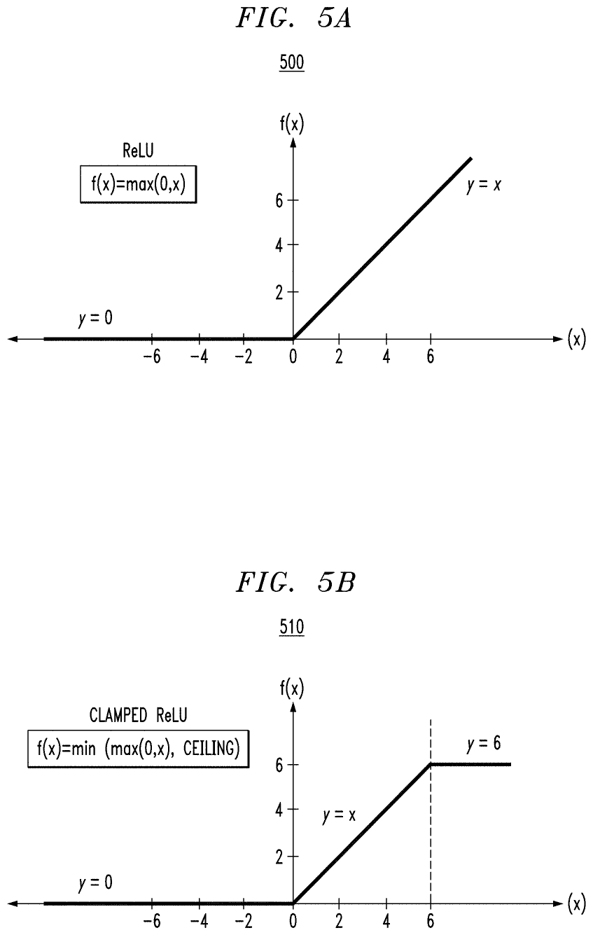

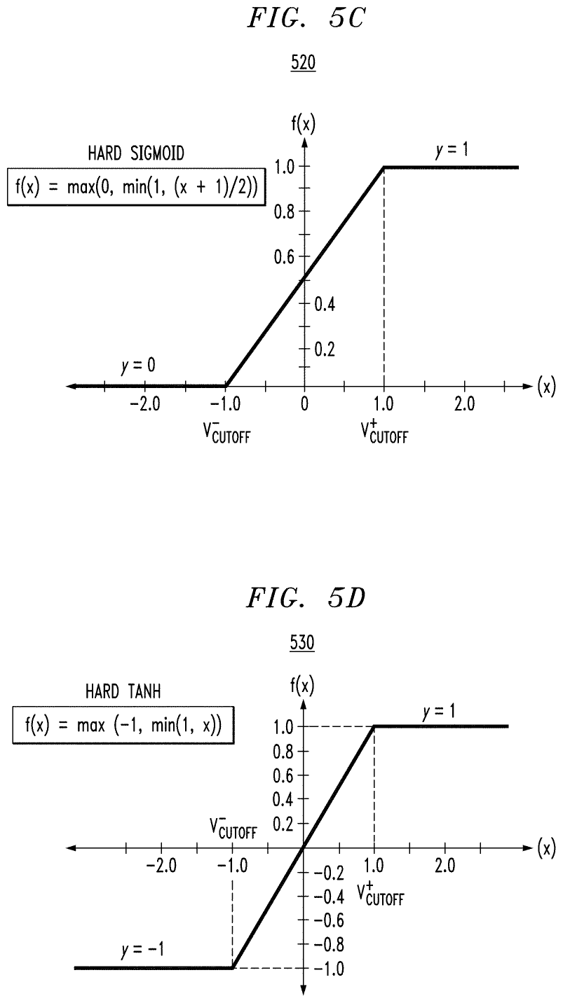

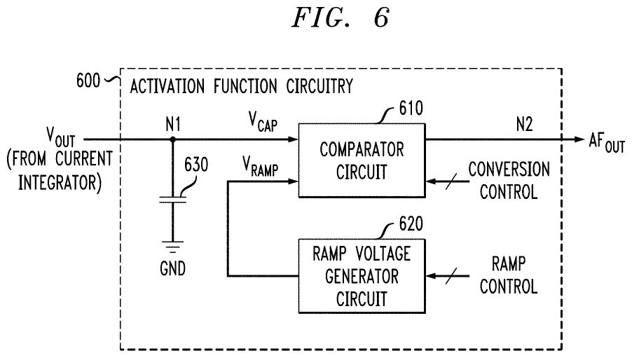

Because of programming errors and/or non-idealities of the analog resistive memory crossbar array hardware (e.g., analog RPU hardware), the target (expected) behavior of the analog RPU hardware (based on the actual weight values of the given matrix of trained/target weight values W_{T}) may be different from the actual behavior of the analog RPU hardware with respect to hardware accelerated computations (e.g., matrix-vector multiplication operations, vector-matrix multiplication operations, matrix-matrix multiplication operations, vector-vector outer product operations, etc.) that are performed using the analog RPU hardware with the programmed matrix weight values W_{P} which represents the given matrix of trained/target weight values W_{T}. For example, the analog RPU hardware can exhibit line-to-line variations of input/output (I/O) lines (e.g., column-to-column variations or row-to-row variations) which can result in significant errors of the MAC results that are obtained from the hardware matrix-vector multiplication operations, e.g., the columns of the RPU array exhibit different offsets, slopes, and/or spread in the MAC results that are output from the columns. Such errors will be discussed in further detail below in conjunction with FIG. 5.

As noted above, the analog crossbar array calibration process 134 implements methods for calibrating the analog RPU hardware of the neural cores 122 to reduce hardware computation errors that arise due to weight programming errors and/or non-idealities of the analog RPU hardware. In some embodiments, as shown in FIG. 1B, the analog crossbar array calibration process 134 implements a multiphase calibration process comprising the first calibration process 134-1, the second calibration process 134-2, and the third calibration process 134-3. In some embodiments, the first calibration process 134-1 comprises an iterative process that is configured to reduce offset variation between I/O lines (e.g., column lines) of a given analog RPU array, and to reduce a spread (e.g., variance) of MAC results that are output from each of the I/O lines (e.g., column lines) of the analog RPU array, when performing hardware accelerated computations such as vector-matrix or matrix-vector multiplication operations.

In some embodiments, the first calibration process 134-1 implements an iterative method which involves adjusting a “zero vector” for the given analog RPU array and tuning the programmed weights of a weight matrix stored in the analog RPU array, to reduce the line-to-line offset variation and the spread of MAC distribution results, which are generated on output lines (e.g., column lines) of the analog RPU array. In some embodiments, the first calibration process 134-1 implements a Newton-Raphson method which involves adjusting a “zero element” for each output line (e.g., column line) of the analog RPU array, and re-programming the weight values of the weight matrix stored in the analog RPU array, until a convergence criterion is met for each output line in which a difference (error err) between a target offset value, and an actual offset of the given output line does not exceed an error threshold value E. An exemplary embodiment of the first calibration process 134-1 will be discussed in further detail below in conjunction with, e.g., FIGS. 8 and 9A, 9B, and 10.

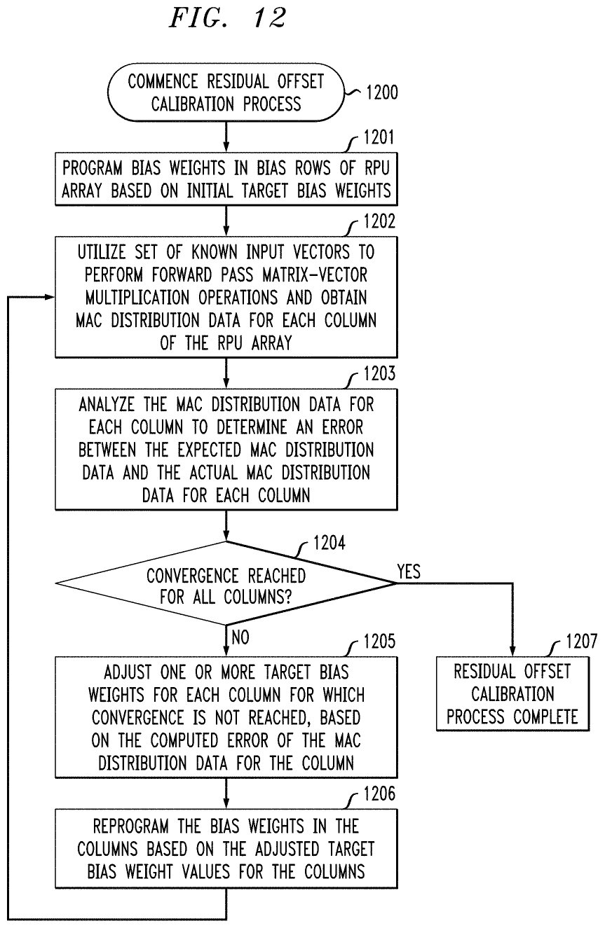

Further, in some embodiments, the second calibration process 134-2 implements a method to reduce the line-to-line slope variation of MAC distribution results, which are generated on output lines (e.g., column lines) of the analog RPU array. In some embodiments, the second calibration process 134-2 is performed following the first calibration process 134-1. While the first calibration process 134-1 may result in reducing the line-to-line offset variation and reducing the spread, there may still exist a line-to-line slope variation between output lines (e.g., column lines) of the analog RPU array. In some embodiments, the second calibration process 134-2 involves analyzing the MAC distribution data for each output line (e.g., column line) of the analog RPU array to construct a respective straight line that fits to the MAC distribution data and determine a slope of the constructed straight line. The determined slope is compared to a target slope, and a weight scaling factor is determined based on the variation of the determined slope from the target slope. A weight programming process is then performed to scale the weight values in each output line (e.g., column line) of the weight matrix stored in the analog RPU array based on the determined scaling factor determined for the given output line. An exemplary embodiment of the second calibration process 134-2 will be discussed in further detail below in conjunction with, e.g., FIGS. 8 and 11.

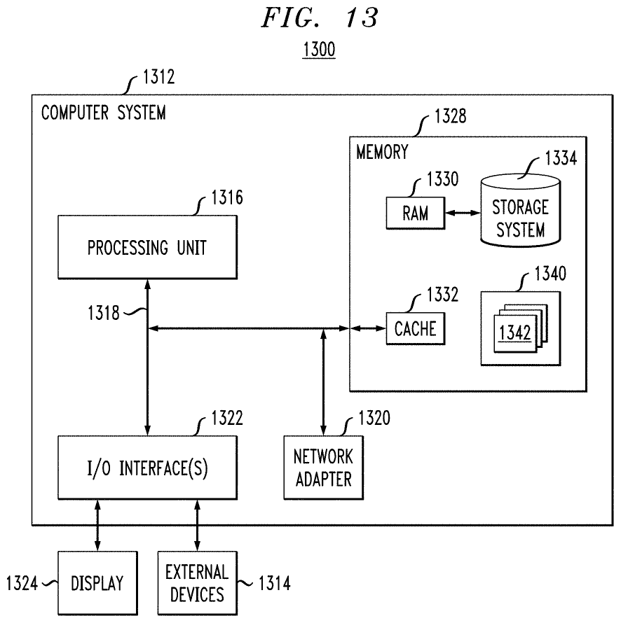

Next, in some embodiments, the third calibration process 134-3 implements an iterative method which involves adjusting bias weights stored in the given analog RPU array for the output lines to reduce any residual line-to-line offset variation of the output lines (e.g., column lines) of the analog RPU array. In some embodiments, the third calibration process 134-3 implements a Newton-Raphson method which involves adjusting bias weights for each output line (e.g., column line) until a convergence criterion is met for each output line. The third calibration process 134-3 is configured to finely adjust the line-to-line variation to reduce any residual offset line-to-line variation which exists at the completion of the first calibration process 134-1. However, the programmed weight values of the matrix, and the zero elements for each output line are not adjusted during the third calibration process 134-3. An exemplary embodiment of the third calibration process 134-3 will be discussed in further detail below in conjunction with, e.g., FIGS. 8 and 12.

The analog crossbar array calibration process 134 serves to calibrate a given analog RPU array, which stores a given weight matrix, by reducing line-to-line variations with respect to offset and slope, and reducing spread, with respect to computations that are performed using the given analog RPU array. The calibration of the analog RPU array with the stored weight matrix serves to reduce hardware computation errors that arise due to weight programming errors and/or non-idealities of the analog RPU hardware. Following the analog crossbar array calibration process 134, the calibrated analog RPU array(s) can be utilized to perform hardware accelerated computations for a given application.

For example, the inference/classification process 136 implements methods that are configured to perform inference, classification and/or AI processes using the artificial neural network 124 which is configured and calibrated in the analog RPU hardware. The inference/classification process 136 may be implemented using the artificial neural network 124 for applications such as machine learning and inference processing for cognitive computing tasks such as object recognition, image recognition, speech recognition, handwriting recognition, natural language processing, etc. Further, as noted above, a given analog RPU array can be configured to store a given matrix that is provided by any type of application which utilizes matrices as computational objects to perform numerical operations for, e.g., solving linear equations, and performing other computations which are based on, e.g., vector-matrix multiplication operations, matrix-vector multiplication operations, matrix-matrix multiplication operations, etc.

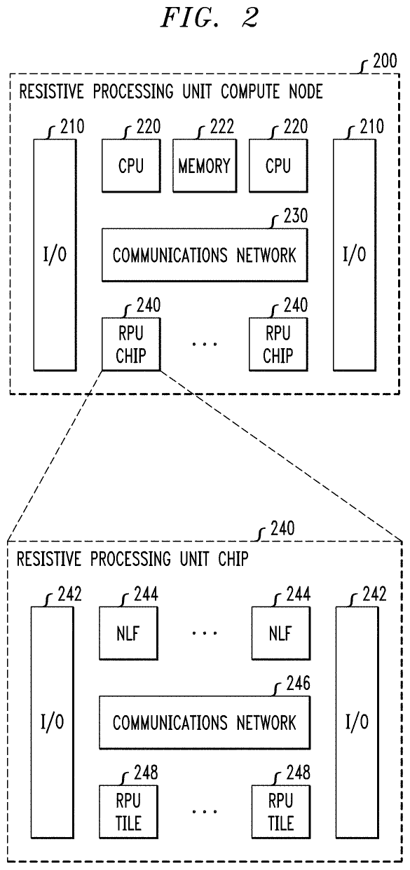

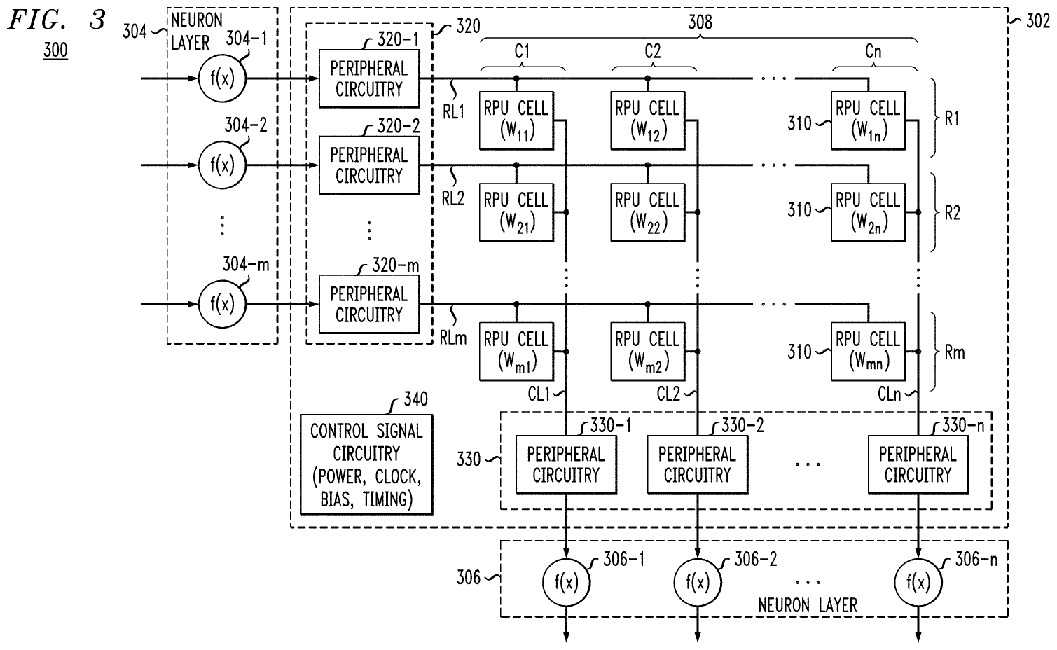

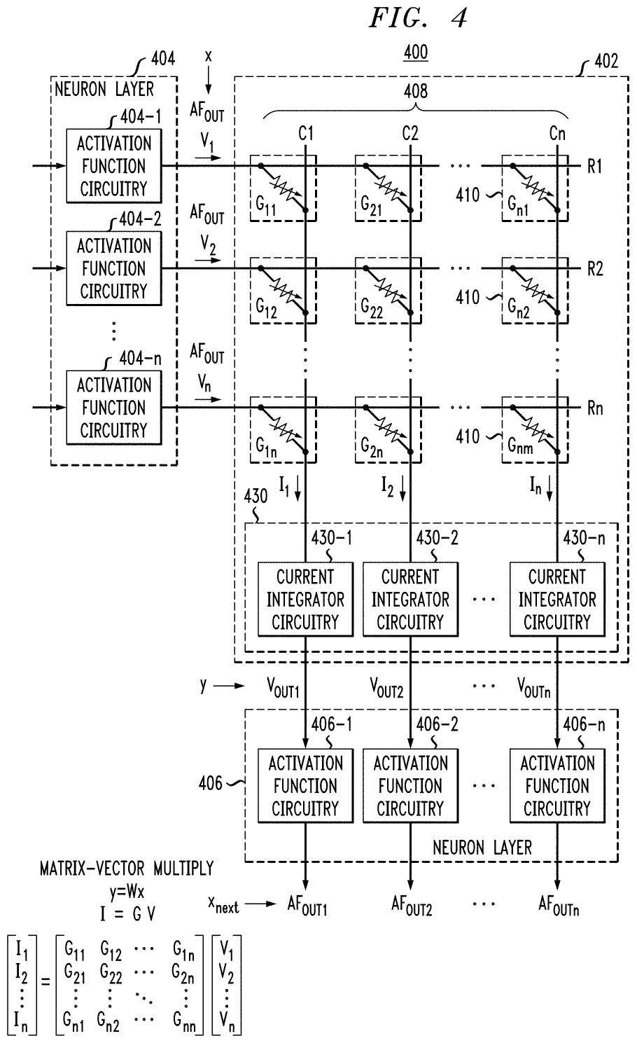

As noted above, in some embodiments, the neuromorphic computing system 120 of FIG. 1 comprises an RPU system in which the neural cores 122 are implemented using one or more RPU compute nodes having RPU devices (e.g., RPU accelerator chips). For example, in some embodiments, the computing system 100 is implemented using an RPU computing system as shown in FIG. 2. In particular, FIG. 2 schematically illustrates an RPU compute node 200 comprising one or more I/O interfaces 210, one or more processors 220 (e.g., CPUs, GPUs, etc.), memory 222 (e.g., volatile memory, and non-volatile memory), a communications network 230, and one or more RPU chips 240. In some embodiments, as shown in FIG. 2, each RPU chip 240 comprises a plurality of I/O interfaces 242, a plurality of non-linear function (NLF) compute modules 244, an intranode communications network 246, and a plurality of RPU tiles 248. The I/O interfaces 242 comprise circuitry to enable off-chip I/O communication. Each RPU tile 248 comprises an array of RPU cells (or RPU array) and peripheral circuitry. Exemplary embodiments of the RPU tiles 248 will be described in further detail below with reference to FIGS. 3 and 4.

In some embodiments, the processors 220 comprises digital processing units of the RPU compute node 200, which execute program code that is stored in the memory 222 to perform software functions to support neuromorphic computing applications. For example, in some embodiments, the processors 220 execute program code to perform the processes 130, 132, 134, and 136 (FIG. 1), and other software functions that utilize the analog RPU hardware for hardware accelerated computing. The RPU compute node 200 is configurable for different applications using different program instruction sets that are executed by the processors 220 to perform desired processes and computational tasks. In some embodiments, the processors 220 are configured to convert digital inputs/outputs to analog inputs/outputs. The processors 220 execute program code to configure, calibrate, and utilize the RPU chips 240 to perform accelerated analog computations. In some embodiments, the processors 220 are configured to move data within the given RPU compute node 200 and between different RPU compute nodes. In some embodiments, depending on the size of the artificial neural network 124, two or more RPU compute nodes 200 can be utilized to implement the artificial neural network 124.

On the RPU chip, for an artificial neural network application, the RPU tiles 248 are configured to implement synaptic device arrays, and the NLF compute modules 244 are configured as artificial neurons that implement activation functions such as hardware activation functions as discussed herein. More specifically, in some embodiments, the neuronal functionality is implemented by the NLF compute modules 244 using standard CMOS circuitry, while the synaptic functionality is implemented by the RPU tiles 248 which, in some embodiments, comprise densely integrated crossbar arrays of analog resistive memory devices. The intranode communications network 246 enables on-chip communication (between neurons and synaptic device arrays) through a bus or any suitable network-on-chip (NoC) communications framework.

FIG. 3 schematically illustrates an RPU system 300 which is configured to implement an artificial neural network comprising artificial neurons and artificial synaptic device arrays, according to an exemplary embodiment of the disclosure. The RPU system 300 comprises an RPU crossbar system 302 (or RPU tile), a first neuron layer 304, and a second neuron layer 306. The first neuron layer 304 comprises a plurality of artificial neurons 304-1, 304-2, . . . , 304-m (or nodes) which implement respective activation functions f(x), and the second neuron layer 306 comprises a plurality of artificial neurons 306-1, 306-2, . . . , 306-n (or nodes) which implement respective activation functions f(x). In some embodiments, the first neuron layer 304 comprises an input layer or intermediate (hidden) layer of an artificial neural network, and the second neuron layer 306 comprises an intermediate (hidden) layer or output layer of the artificial neural network, wherein the first neuron layer 304 comprises an upstream layer of artificial neurons that are coupled to the downstream second neuron layer 306 by the RPU crossbar system 302. In some embodiments, FIG. 3 schematically illustrates an exemplary architecture of at least one RPU chip 240 of FIG. 2, wherein the first and second neuron layers 304 and 306 are implemented using the NLF compute modules 244, and the RPU crossbar system 302 comprises an RPU tile 248.

As shown in FIG. 3, the RPU crossbar system 302 comprises an RPU array 308 (e.g., crossbar array) which comprises RPU cells 310 arranged in a plurality of rows R1, R2, . . . , Rm, and a plurality of columns C1, C2, . . . , Cn. The RPU cells 310 in each row R1, R2, . . . , Rm are commonly connected to respective row lines RL1, RL2, . . . , RLm (collectively, row lines RL). The RPU cells 310 in each column C1, C2, . . . , Cn are commonly connected to respective column lines CL1, CL2, . . . , CLn (collectively, column lines CL). Each RPU cell 310 is connected at (and between) a cross-point (or intersection) of a respective one of the row and column lines. The row lines RL comprise conductive input/output (I/O) lines that extend in a first direction across the RPU array 308, and the column lines CL comprises conductive I/O lines that extend in a second direction across the RPU array 308, orthogonal to the first direction.

In some embodiments, depending on the configuration of the RPU system 300, the row lines RL are utilized as signal input lines to the RPU array 308, and the column lines CL are utilized as signal output lines from the RPU array 308, while in other embodiments, the column lines CL are utilized as signal input lines to the RPU array 308, and the row lines RL are utilized as signal output lines from the RPU array 308. In some embodiments, the number of rows (m) and the number of columns (n) are different, while in other embodiments, the number of rows (m) and the number of columns (n) are the same (i.e., m=n). For example, in an exemplary non-limiting embodiment, the RPU array 308 comprises a 4,096×4,096 array of RPU cells 310.

The RPU crossbar system 302 further comprises peripheral circuitry 320 coupled to the row lines RL1, RL2, . . . , RLm, as well as peripheral circuitry 330 coupled to the column lines CL1, CL2, . . . , CLn. More specifically, the peripheral circuitry 320 comprises blocks of peripheral circuitry 320-1, 320-2, . . . , 320-m (collectively peripheral circuitry 320) connected to respective row lines RL1, RL2, . . . , RLm, and the peripheral circuitry 330 comprises blocks of peripheral circuitry 330-1, 330-2, . . . , 330-n (collectively, peripheral circuitry 330) connected to respective column lines CL1, CL2, . . . , CLn. The RPU crossbar system 302 further comprises local control signal circuitry 340 which comprises various types of circuit blocks such as power, clock, bias and timing circuitry to provide power distribution, control signals, and clocking signals for operation of the peripheral circuitry 320 and 330 of the RPU crossbar system 302, as well as the activation function circuitry which performs the activation functions of the first neuron layer 304, and/or the second neuron layer 306, as discussed in further detail below. While the row lines RL and column lines CL are each shown in FIG. 3 as a single line for ease of illustration, it is to be understood that each row line and column line can include two or more lines connected to the RPU cells 310 in the respective rows and columns, depending on the specific architecture of the RPU cells 310 and/or RPU array 308, as is understood by those of ordinary skill in the art.

In some embodiments, each RPU cell 310 in the RPU crossbar system 302 comprises a resistive memory element with a tunable conductance. For example, the resistive memory elements of the RPU cells 310 can be implemented using resistive devices such as resistive switching devices (interfacial or filamentary switching devices), ReRAM, memristor devices, phase change memory (PCM) devices, and other types of resistive memory devices having a tunable conductance (or tunable resistance level) which can be programmatically adjusted within a range of a plurality of different conductance levels to tune the values (e.g., matrix values, synaptic weights, etc.) of the RPU cells 310. In some embodiments, the variable conductance elements of the RPU cells 310 can be implemented using ferroelectric devices such as ferroelectric field-effect transistor devices. Furthermore, in some embodiments, the RPU cells 310 can be implemented using an analog CMOS-based framework in which each RPU cell 310 comprises a capacitor and a read transistor. With the analog CMOS-based framework, the capacitor serves as a memory element of the RPU cell 310 and stores a weight value in the form a capacitor voltage, and the capacitor voltage is applied to a gate terminal of the read transistor to modulate a channel resistance of the read transistor based on the level of the capacitor voltage, wherein the channel resistance of the read transistor represents the conductance of the RPU cell and is correlated to a level of a read current that is generated based on the channel resistance.

For certain applications, some or all of the RPU cells 310 within the RPU array 308 comprise respective conductance values that are mapped to respective numerical matrix values of a given matrix W (e.g., computational matrix or synaptic weight matrix, etc.) that is stored in the RPU array 308. For example, for an artificial neural network application, some or all of the RPU cells 310 with the RPU array 308 serve as artificial synaptic devices that are encoded with synaptic weights of a synaptic array which connects two layers of artificial neurons of the artificial neural network. More specifically, in an exemplary embodiment, the RPU array 308 comprises an array of artificial synaptic devices which connect artificial pre-synaptic neurons (e.g., the artificial neurons of the first neuron layer 304) and artificial post-synaptic neurons (e.g., the artificial neurons of the second neuron layer 306), wherein the artificial synaptic devices provide synaptic weights that represent connection strengths between the pre-synaptic and post-synaptic neurons. As shown in FIG. 3, the weights Wᵢⱼ are in the form of a matrix, wherein i denotes the row index and j denotes the column index. While FIG. 3 shows an exemplary embodiment in which all RPU cells 310 encoded with a given weight value for a weight matrix W with a size of m×n, the RPU array 308 can be configured to store a weight matrix with dimensions smaller than m×n.

In addition, in some embodiments, when the row lines are configured as input lines, and the column lines are configured as output lines, the RPU array 308 may comprise one or more rows of RPU cells 310 that store bias weights that are tuned (e.g., as part of the third calibration process 134-3) to rigidly adjust (up or down) the offset of MAC results that are output from each column of RPU cells 310 of the RPU array 308 which comprise programed weights of a given weight matrix stored in the RPU array 308. By way of example, for a weight matrix W with a size of 512×512, the RPU array 308 can include 8 additional rows of bias weights which are interspersed between the rows of matrix weights (e.g., one row of bias weights disposed every 63 rows of matrix weights). In other embodiments, when the column lines are configured as input lines, and the row lines are configured as output lines, the RPU array 308 may comprise one or more columns of RPU cells 310 that store bias weights that are tuned (e.g., as part of the third calibration process 134-3) to rigidly adjust (up or down) the offset of MAC results that are output from each row of RPU cells 310 of the RPU array 308 which comprise programed weights of a given weight matrix stored in the RPU array 308.

The peripheral circuitry 320 and 330 comprises various circuit blocks that are configured to perform functions such as, e.g., programming the conductance values of the RPU cells 310 to store encoded values (e.g., matrix values, synaptic weights, etc.), reading the programmed states of the RPU cells 310, and performing functions to support analog, in-memory computation operations such as vector-matrix multiply operations, matrix-vector multiply operation, matrix-matrix multiply operations, vector-vector outer product operations, etc., for a given application (e.g., inference/classification using a trained neural network, etc.). For example, in some embodiments, the blocks of peripheral circuitry 320-1, 320-2, . . . , 320-m comprise corresponding pulse-width modulation (PWM) circuitry and associated driver circuitry, and readout circuitry for each row of RPU cells 310 of the RPU array 308. Similarly, the blocks of peripheral circuitry 330-1, 330-2, . . . , 330-n comprises corresponding PWM circuitry and associated driver circuitry, and readout circuitry for each column of RPU cells 310 of the RPU array 308.

In some embodiments, the PWM circuitry and associated pulse driver circuitry of the peripheral circuitry 320 and 330 is configured to generate and apply PWM read pulses to the rows and columns of the array of RPU cells 310 in response to digital input vector values (read input values) that are received during different operations (e.g., programming operations, forward pass computations, etc.). In some embodiments, the PWM circuitry is configured to receive a digital input vector (to be applied to rows or columns) and convert the elements of the digital input vector into analog input vector values that are represented by input voltage voltages of varying pulse width. In some embodiments, a time-encoding scheme is used when input vectors are represented by fixed amplitude V_{IN}=1V pulses with a tunable duration (e.g., pulse duration is a multiple of ins and is proportional to the value of the input vector). The input voltages applied to the rows (or columns) generate output MAC values on the columns (or rows) which are represented by output currents, wherein the output currents are processed by the readout circuitry.

For example, in some embodiments, the readout circuitry of the peripheral circuitry 320 and 330 comprises current integrator circuitry that is configured to integrate the read currents which are output and accumulated from the columns or rows of connected RPU cells 310 and convert the integrated currents into analog voltages for subsequent computation. In particular, the currents generated by the RPU cells 310 are summed on the columns (or rows) and the summed current is integrated over a measurement time, or integration time T_{INT}, by the readout circuitry of the peripheral circuitry 320 and 330. In some embodiments, each current integrator comprises an operational amplifier that integrates the current output from a given column (or row) (or differential currents from pairs of RPU cells implementing negative and positive weights) on a capacitor.

The configuration of the peripheral circuitry 320 and 330 will vary depending on, e.g., the hardware configuration (e.g., digital or analog processing) of the artificial neurons. In some embodiments, the artificial neurons of the first and second neuron layers 304 and 306 comprise analog functional units, which can be implemented in whole in or part using the peripheral circuitry 320 and 330 of the RPU crossbar system 302. In some embodiments, when a given neuron layer implements neuron activation functions in the digital domain, the peripheral circuitry of the RPU crossbar system 302 is configured to convert digital activation input data into analog voltages for processing by the RPU array 308, and/or convert analog activation output data to digital activation data.

In other embodiments, FIG. 4 schematically illustrates a method for configuring a resistive processing unit system to implement an artificial neural network comprising artificial neurons which comprise analog hardware-implemented activation function circuitry, according to an exemplary embodiment of the disclosure. More specifically, FIG. 4 schematically illustrates an RPU system 400 which comprises an RPU crossbar system 402, a first neuron layer 404, and a second neuron layer 406. The RPU crossbar system 402 comprises an RPU array 408 (e.g., crossbar array) which comprises RPU cells 410 arranged in a plurality of rows R1, R2, . . . , Rn, and a plurality of columns C1, C2, . . . , Cn (e.g., number of rows and columns are the same). The RPU crossbar system 402 further comprises readout circuitry 430 which comprises blocks of current integrator circuitry 430-1, 430-2, . . . 430-n, coupled to respective columns C1, C2, . . . , Cn of the RPU array 408.

The first neuron layer 404 comprises blocks of activation function circuitry 404-1, 404-2, . . . , 404-n, which comprise artificial neurons that perform hardware-based activation functions in the analog domain. The blocks of activation function circuitry 404-1, 404-2, . . . , 404-n are coupled to respective rows R1, R2, . . . , Rn of the RPU array 408. Similarly, the second neuron layer 406 comprises blocks of activation function circuitry 406-1, 406-2, . . . , 406-n, which comprise artificial neurons that perform hardware-based activation functions. The blocks of activation function circuitry 406-1, 406-2, . . . , 406-n are coupled to the outputs of the blocks of current integrator circuitry 430-1, 430-2, . . . 430-n, respectively.

In some embodiments, each RPU cell 410 comprises an analog non-volatile resistive memory element (which is represented as a variable resistor having a tunable conductance G) at the intersection of each row R1, R2, . . . , Rn and column C1, C2, . . . , Cn of the RPU array 408. As depicted in FIG. 4, the RPU array 408 comprises a conductance matrix G comprising conductance values Gᵢⱼ, where i represents a row index and j denotes a column index (for illustrative purposes, for mathematical correctness, the RPU array 408 is shown to store a transpose GT of the conductance matrix G). For purposes of illustration, it is assumed that the RPU array 408 comprises a synapse array (or connectivity matrix) of synaptic weights for fully connected layers of an artificial neural network in which n artificial neurons of the first neuron layer 404 (an input layer, or a hidden layer, etc.) are connected to each of n artificial neurons of the second neuron layer 406 (an output layer, or next downstream hidden layer, etc.). The conductance values Gᵢⱼ are mapped to synaptic weights Wᵢⱼ of a given synaptic weight matrix W stored in the RPU array 408, wherein each synaptic weight Wᵢⱼ (encoded by a given conductance value Gᵢⱼ) represents a strength of a connection between two artificial neurons of different layers of the artificial neural network.

FIG. 4 illustrates an exemplary embodiment in which each block of activation function circuitry is configured to generate analog activation output data using an analog-temporal encoding scheme. For example, each block of activation function circuitry is configured to generate an activation output pulse (AF_{OUT}) having a fixed magnitude (e.g., ±V) but with a variable duration (e.g., pulse width) that encodes an activation output value based on an input to the block of activation function circuitry. In some embodiments, the activation output pulses (AF_{OUT}) have a fixed magnitude (e.g., ±V_{DD}) but with a variable pulse duration which is a multiple of a prespecified time period (e.g., 1 nanosecond). When the pulse duration is zero (no output pulse), the activation output value can be deemed zero. When the pulse duration is non-zero, the activation output value is proportional to duration of the activation output pulses.

FIG. 4 schematically illustrates a process to compute neuron activations of the downstream neuron layer 406 based on (i) neuron activations of the upstream neuron layer 404 and (ii) the synaptic weights that connect the artificial neurons (e.g., blocks of activation function circuitry 404-1, 404-2, . . . , 404-n) of the upstream neuron layer 404 to the artificial neurons (e.g., blocks of activation function circuitry 406-1, 406-2, . . . , 406-n) of the blocks of activation function circuitry 404-1, 404-2, . . . , 404-n downstream neuron layer 406. In particular, as shown in FIG. 4, the activation data, which is generated by the blocks of activation function circuitry 404-1, 404-2, . . . , 404-n of the upstream neuron layer 404, is represented by activation outputs AF_{OUT} which comprise respective analog output pulses V₁, V₂, . . . , Vₙ, which represent an analog input vector x=[V₁, V₂, . . . , Vₙ].

To perform a matrix-vector multiplication, all rows R1, R2, . . . , Rn are concurrently activated and the analog input voltages V₁, V₂, . . . , Vₙ (e.g., pulses), are concurrently applied to the respective rows R1, R2, . . . , Rn. Each RPU cell 410 generates a corresponding read current I_{READ}=Vᵢ×Gᵢⱼ (based on Ohm's law), wherein Vᵢ denotes the analog input voltage applied to the given RPU cell 410 on the given row i and wherein Gᵢⱼ denotes the conductance value of the given RPU cell 410 at the array position i,j). As shown in FIG. 4, the read currents that are generated by the RPU cells 410 on each column C1, C2, . . . , Cn are summed together (based on Kirchhoff's current law) to generate respective aggregate currents I₁, I₂, . . . , Iₙ at the output of the respective columns C1, C2, . . . , Cn. For example, the aggregate current I₁ for the first column C1 is determined as I₁=(V₁G₁₁+V₂ G₁₂+, . . . , +Vₙ G₁ₙ).

The resulting aggregate read currents I₁, I₂, . . . , Iₙ at the output of the respective columns C1, C2, . . . , Cn are input to respective blocks of current integrator circuitry 430-1, 430-2, . . . , 430-n, wherein the aggregate read currents I₁, I₂, . . . , Iₙ are integrated over a specified integration time T_{INT} to generate respective output voltages V_{OUT1}, V_{OUT2}, . . . , V_{OUTn}. The current integrator circuitry 430-1, 430-2, . . . , 430-n can be implemented using any type of current integrator circuitry which is suitable for the given application to perform an integration function over an integration period (T_{INT}) to convert the aggregated current outputs I₁, I₂, . . . , Iₙ from the respective column lines C1, C2, . . . , Cn, to respective analog voltages V_{OUT1}, V_{OUT2}, V_{OUTn} at the output nodes of the current integrator circuitry 430-1, 430-2, . . . , 430-n. For example, in some embodiments, each current integrator circuit comprises an operational transconductance amplifier (OTA) with capacitive feedback provided by one or more integrating capacitors to convert the aggregate input current (e.g., aggregate column current) to an output voltage V_{OUT}.

The output voltages V_{OUT1}, V_{OUT2}, V_{OUTn} comprise a resulting output vector y=[VOUT₁, V_{OUT2}, . . . , V_{OUTn}], which represents the result of the matrix-vector multiplication operation y=Wx (or I=GV). As noted above, for mathematical correctness of the equation, y=Wx, the matrix-vector multiplication operation y=Wx for the forward pass operation shown in FIG. 4 can be performed by (i) storing a transpose matrix W^{T} of the a given weight matrix W in the RPU array 408 such that the i^{th} row of the matrix W is stored in the RPU array 408 as the j^{th} column of the transpose matrix W^{T}.

In this manner, each column current I₁, I₂, . . . , Iₙ represents a multiply-and-accumulate (MAC) result for the given column, and wherein the column currents I₁, I₂, . . . , Iₙ (and thus the respective output voltages V_{OUT1}, V_{OUT2}, V_{OUTn}) collectively represent the result of a matrix-vector multiplication operation y=Wx that is performed by the RPU system 400. As such, the matrix W (which is represented by the conductance matrix G of conductance values Gᵢⱼ) is multiplied by the input analog voltage vector x=[V₁, V₂, . . . , Vₙ] to generate and output an analog current vector [I₁, I₂, . . . , Iₙ], as illustrated in FIG. 4.

With the exemplary process shown in FIG. 4, the neuron activations V₁, V₂, . . . , Vₙ of the upstream neuron layer 404 (i.e., the input vector x=[V₁, V₂, . . . , Vₙ]) are linearly transformed into an analog voltage vector y=[V_{OUT1}, V_{OUT2}, V_{OUTn}] via the matrix-vector multiplication operations y=Wx performed using the RPU array 408 encoded with a trained weight matrix W. The analog voltages V_{OUT1}, V_{OUT2}, . . . , V_{OUTn} are input to the respective blocks of activation function circuitry 406-1, 406-2, . . . , 406-n of the downstream neuron layer 406, wherein the analog voltages V_{OUT1}, V_{OUT2}, V_{OUTn} are processed using the activation function circuitry 406-1, 406-2, . . . , 406-n and transformed (e.g., non-linear transforms) into the neuron activations of the downstream neuron layer 406, xnext=[AF_{OUT1}, AF_{OUT2}, AF_{OUTn}]. Iₙ some embodiments, the neuron activation outputs AF_{OUT1}, AF_{OUT2}, AF_{OUTn} of the downstream neuron layer 406 comprise analog-temporal encoded pulses which are input to a next synaptic device array which connects the downstream neuron layer 406 to the next downstream layer of the artificial neutral network.

FIG. 4 illustrates an exemplary embodiment of an RPU system 400 which is configured to perform parallel vector-matrix operations, with excitation vectors applied to multiple row lines and thereby perform MAC operations across an entire matrix of stored weights encoded into the conductance values of analog nonvolatile resistive memories. The RPU array 408 and readout circuitry 430 are configured to generate a summed weighted input (e.g., analog voltages V_{OUT1}, V_{OUT2}, V_{OUTn}) for each neuron (e.g., each activation function circuitry 406-1, 406-2, . . . , 406-n) of the downstream neuron layer 406. The summed weighted inputs V_{OUT1}, V_{OUT2}, V_{OUTn} to the respective neurons are transformed via the activation function circuitry 406-1, 406-2, . . . , 406-n, respectively, into the corresponding outputs or “activations” of the neurons.

FIGS. 5A, 5B, 5C, and 5D graphically illustrate various activation functions which can be implemented in hardware according to exemplary embodiments of the disclosure. In particular, FIG. 5A graphically illustrates a ReLU activation function 500 which can be implemented in hardware using techniques as discussed in further detail below. The ReLU activation function 500 can be defined as: f(x)=max (0, x). The ReLU activation function 500 is linear for all positive values, and zero for all negative values. In other words, the ReLU activation function 500 is a 2-part piecewise linear function in which (i) f(x)=x, when x≥0, and (ii) f(x)=0, when x<0. The ReLU activation function 500 is a commonly used activation function in deep learning models for many types of neural networks. The ReLU activation function 500 is linear for values greater than zero, which provides many of the desirable properties of a linear activation function when performing certain functions. On the other hand, the ReLU activation function 500 is a nonlinear function because negative input values are always output as zero.

Next, FIG. 5B graphically illustrates a clamped ReLU activation function 510 which can be implemented in hardware using techniques as discussed in further detail below. The clamped ReLU activation function 510 is similar to the ReLU activation function 500 of FIG. 5A, except that the clamped ReLU activation function 510 performs a threshold operation in which any positive input value above a ceiling threshold value is set to the ceiling threshold value. The clamped ReLU activation function 510 can be defined as: f(x)=min (max(0, x), ceiling). In particular, for the clamped ReLU activation function 510: (i) f(x)=0, when x<0, (ii) f(x)=x, when 0≤x<ceiling, and (iii) f(x)=ceiling, when x≥ceiling. The clamped ReLU activation function 510 is configured to prevent the activation output value from becoming too large. For example, in the exemplary embodiment shown in FIG. 5B, the ceiling threshold value is set to six (6), so that any output value greater than 6 will be set to the ceiling (clamped) value of 6.

Next, FIG. 5C graphically illustrates a hard sigmoid activation function 520 which can be implemented in hardware using techniques as discussed in further detail below. The hard sigmoid activation function 520 is a 3-part piecewise linear approximation of the sigmoid function, which eliminates the need to compute the exponent of the sigmoid function. In some embodiments, the hard sigmoid activation function 520 can be defined as:

$$f ( x ) = max ( 0 , min ( 1 , \frac{( x + 1 )}{2} ) ) ,$$

such as shown in FIG. 5C, wherein the input (x) value to the hard sigmoid activation function 520 is transformed into a value in a range from 0.0 and 1.0. More specifically, the exemplary hard sigmoid activation function 520 comprises a positive voltage cutoff V⁺_{CUTOFF}=1.0 and a negative voltage cutoff V⁻_{CUTOFF}=−1.0. When the input (x) value is larger than V⁺_{CUTOFF}=1.0, the output will be set to a value of 1.0 (i.e., input (x) values that are larger than V⁺_{CUTOFF} are transformed to a value of 1.0). Similarly, when the input (x) value is less than V⁻_{CUTOFF}=−1.0, the output value is set to a value of 0 (i.e., input (x) values that are less than—V⁻_{CUTOFF} are transformed to a value of 0). Further, input (x) values in the range [−1.0, 1.0] linearly increase from 0 to 1.0, wherein an input value of 0 corresponds to an activation output value of 0.5.

It is to be understood that the hard sigmoid activation function can be configured differently for different applications. For example, in some embodiments, a hard sigmoid activation function can be defined as f(x)=max (0, min(1, (0.2 x+0.5))). With this exemplary hard sigmoid activation function configuration, V⁺_{CUTOFF}=2.5 and V⁻_{CUTOFF}=−2.5, such that f(x)=0, when x<−2.5, and f(x)=1, when x>+2.5. In addition, f(x) linearly increases from 0 to 1 in the range of [−2.5, +2.5]. In other embodiments, a hard sigmoid activation function can be configured such that (i) f(x)=0, when x<V⁻_{CUTOFF}=−3.0, (ii) f(x)=1, when x>V⁺_{CUTOFF}=3.0, and (iii) f(x) linearly increases from 0 to 1 in the range of [−3.0, +3.0].

Next, FIG. 5D graphically illustrates a hard tanh activation function 530 which can be implemented in hardware using techniques as discussed in further detail below. The hard tanh activation function 530 is a 3-part piecewise linear approximation of the tanh function, which eliminates the need to compute, e.g., the exponents of the tanh function. The hard tanh activation function 530 is defined as f (x)=max(−1, min(1, x)). The hard sigmoid activation function 530 comprises a positive voltage cutoff V⁺_{CUTOFF}=1.0 and a negative voltage cutoff V⁻_{CUTOFF}=−1.0. When the input (x) value is larger than V⁺_{CUTOFF}=1.0, the output will be set to a value of 1.0 (i.e., input (x) values that are larger than V⁺_{CUTOFF}=1.0 are transformed to a value of 1.0). Similarly, when the input (x) value is less than V⁻_{CUTOFF}=−1.0, the output value is set to −1 (i.e., input (x) values that are less than V⁻_{CUTOFF}=−1.0 are transformed to a value of −1.0). Further, input (x) values in the range [−1.0, 1.0] linearly increase from −1.0 to 1.0, wherein an input value of 0 corresponds to an output value of 0.

FIG. 6 schematically illustrates activation function circuitry which is configurable to implement a hardware activation function, according to an exemplary embodiment of the invention. In particular, FIG. 6 is a high-level schematic illustration of activation function circuitry 600 which comprises a comparator circuit 610, a ramp voltage generator circuit 620, and a capacitor 630. The comparator circuit 610 comprises (i) a first input terminal (e.g., non-inverting input terminal) that is coupled to an input node N1, (ii) a second input terminal (e.g., inverting input terminal) that is coupled to an output of the ramp voltage generator circuit 620, and (iii) an output terminal that is coupled to an output node N2. The capacitor 630 is coupled between the input node N1 of the activation function circuitry 600, and a negative power supply node (e.g., ground (GND) node). The ramp voltage generator circuit 620 is configured to generate a linear ramp voltage V_{RAMP} which is applied to the second input terminal of the comparator circuit 610. The comparator circuit 610 and the ramp voltage generator circuit 620 are configured and controlled by control signals (e.g., conversion control signals, and ramp control signals, respectively) that are generated by timing and control circuitry which, in some embodiments, comprises the local control circuitry that is implemented for a given RPU tile (e.g., local control signal circuitry 340, FIG. 3) to control functions and operations of the RPU tile.

In some embodiments, FIG. 6 schematically illustrates a hardware implementation of given artificial neuron of an artificial neural network in which (i) the activation function circuitry 600 receives an output voltage V_{OUT} (from a given current integrator circuit) which represents the multiply-accumulate (MAC) result that is output from a given output line (e.g., column line) of an RPU array, and (ii) the activation function circuitry 600 is configured to implement a non-linear activation function which transforms the MAC result (summed weighted input) into the specific output or “activation” (AF_{OUT}) for the given artificial neuron. In some embodiments, as explained in further detail below, for artificial neural network applications, the activation function circuitry 600 is configurable to implement one of a plurality of different types of non-linear activation functions such as, e.g., a ReLU activation function, a clamped ReLU activation function, a hard sigmoid activation function, a hard tanh activation function, etc. In addition, for matrix computations other than neural network applications, the activation function circuitry 600 is configured to implement a linear activation function.

In some embodiments, the activation function circuitry 600 of FIG. 6 comprises an exemplary circuit architecture for implementing, e.g., each block of activation function circuitry 406-1, 406-2, . . . , 406-n (as shown in FIG. 4). During an integration period T_{INT}, the summed current (e.g., I₁) generated on a given column line (e.g., C1) of the RPU array 408 is converted by a given current integrator circuit (e.g., current integrator circuitry 430-1) to an analog output voltage V_{OUT} (e.g., V_{OUT1}). At the end of the integration period T_{INT}, as shown in FIG. 6, the output voltage V_{OUT} (generated by the current integrator circuitry) is applied to the input node N1 of the activation function circuitry 600 to charge a capacitor voltage V_{CAP} of the capacitor 630 to V_{OUT} during a relatively short charging period which occurs prior to the start of a conversion period (denoted T_{CONVERSION}).

During a conversion period T_{CONVERSION}, the activation function circuitry 600 is configured to convert (or transform) the capacitor voltage V_{CAP} (which corresponds to V_{OUT}) to an output value AF_{OUT} of the non-linear activation function which is implemented by the activation function circuitry 600. More specifically, during the conversion period T_{CONVERSION}, the comparator circuit 610 is configured to continuously compare the stored capacitor voltage V_{CAP} (which equal or substantially equal to V_{OUT}) to the linear ramp voltage V_{RAMP}, and generate a voltage pulse on the output terminal thereof, based on a result of the continuous comparing during the conversion period. The voltage pulse that is generated by the comparator circuit 610 comprises a pulse duration which encodes an activation output value AF_{OUT} of the non-linear activation function based on the input value (e.g., V_{OUT}) to the non-linear activation function which is implemented by the activation function circuitry 600.

In some embodiments, the activation function circuitry 600 comprises a precharge circuit which is configured to generate a precharge voltage (V_{PRECHARGE}) to precharge the capacitor 630 before the start of a given conversion period. More specifically, in some embodiments, during a precharge period, the capacitor voltage V_{CAP} of the capacitor 630 is charged to a precharge voltage level V_{PRECHARGE}, wherein the precharge voltage level corresponds to a zero-level input to the non-linear activation function implemented by the activation function circuitry 600. The precharging of the capacitor 630 enables the capacitor voltage V_{CAP} to increase or decrease to the level of V_{OUT} (from the precharged voltage level V_{PRECHARGE}) in a relatively short amount of time before the start of the conversion period.

In some embodiments, the timing (e.g., duration, start time, end time) of the conversion period is controlled by conversion control signals that are generated and input to the comparator circuit 610 by the timing and control circuitry. For example, the conversion control signals are configured to enable the operation of the comparator circuit 610 at the start of a given conversion period, and disable operation of the comparator circuit 610 at the end of the given conversion period. Further, in some embodiments, various operating parameters of the ramp voltage generator circuit 620 such as timing (e.g., duration, start time, end time) of the linear ramp voltage signal V_{RAMP}, and the voltage levels (e.g., minimum voltage level, maximum voltage level) of the linear ramp voltage signal V_{RAMP} can be adjusted and controlled by ramp control single that are generated and input to the ramp voltage generator circuit 620 by the timing and control circuitry. The operating parameters of the comparator circuit 610 and the ramp voltage generator circuit 620 can be independently adjusted and controlled to configure the activation function circuitry 600 to implement a desired non-linear activation function or a linear activation function, as needed for the given application.

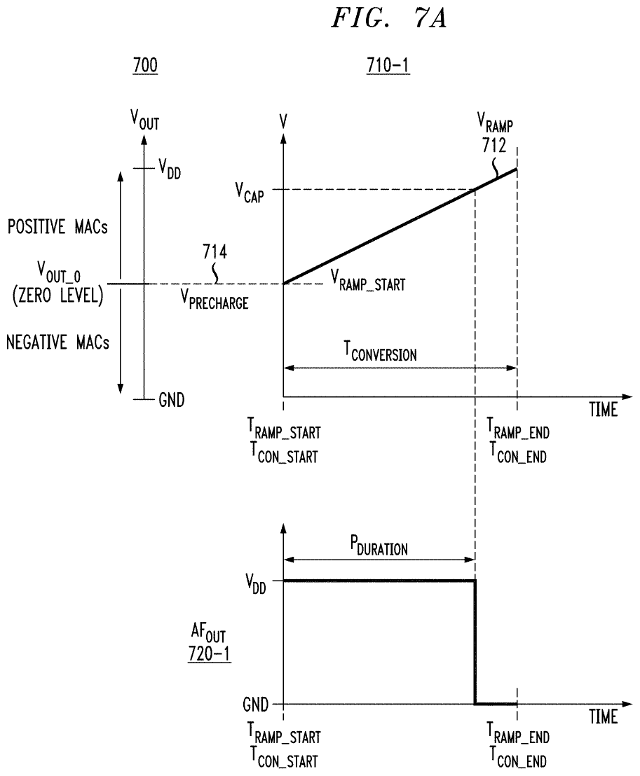

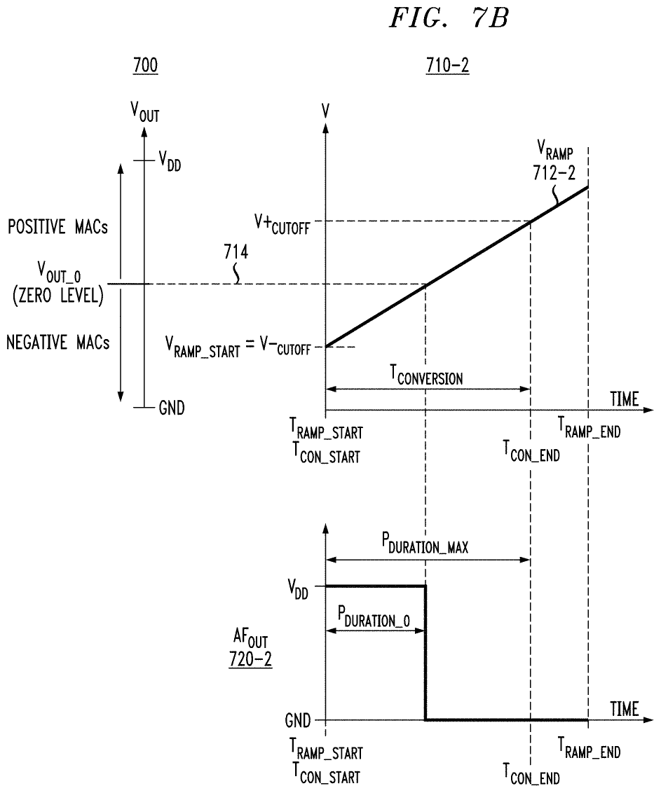

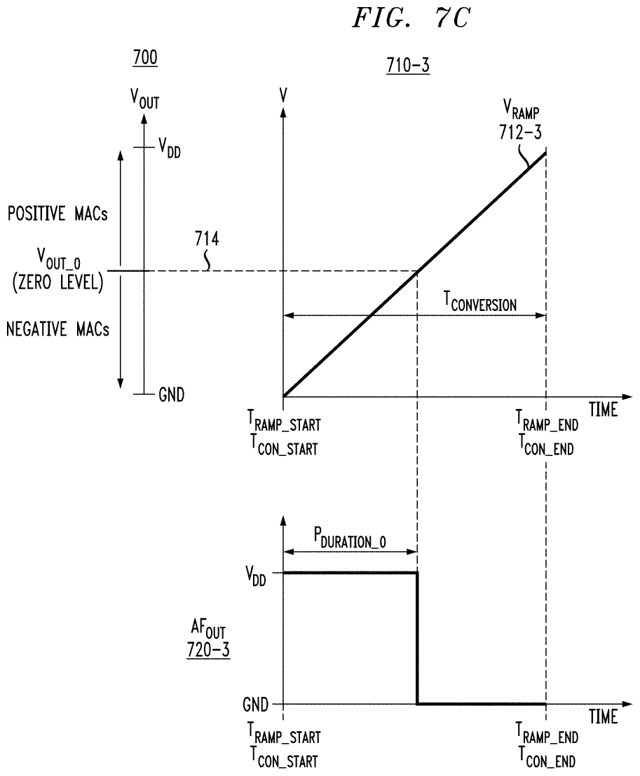

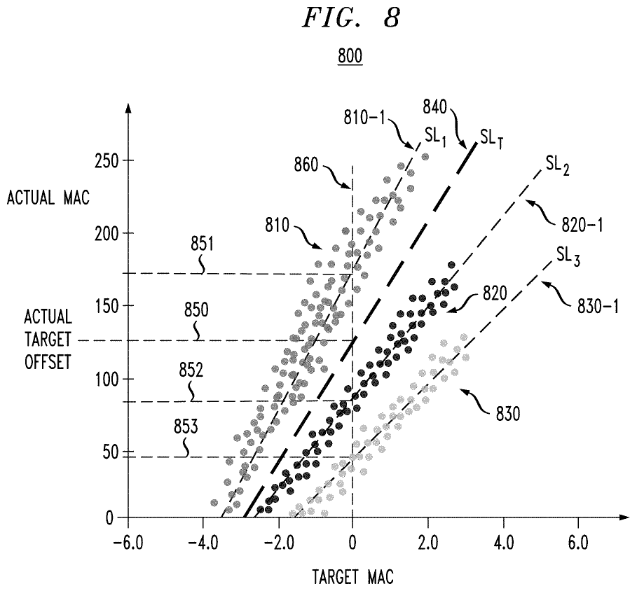

For example, FIG. 7A schematically illustrates operation the activation function circuitry 600 configured to implement a ReLU activation function, according to an exemplary embodiment of the disclosure. In particular, FIG. 7A schematically illustrates a mapping 700 of output voltages V_{OUT} to a range of positive MAC values, a range of negative MAC values, and a zero MAC value. In some embodiments, the output voltages V_{OUT} (which are output from the current integrator circuits 430-1, 430-2, . . . 430-n, FIG. 4) fall within the range of GND (e.g., 0 V) and V_{DD}. The zero level MAC value is mapped to a specified V_{OUT} level (denoted V_{OUT_0}) between GND and V_{DD}, wherein the range of V_{OUT} voltage levels greater than V_{OUT_0} and up to V_{DD} are mapped to a range of positive MAC values, and wherein range of V_{OUT} volage levels less than V_{OUT_0} and down to GND are mapped to a range of negative MAC values.

Further, FIG. 7A depicts a timing diagram 710-1 which schematically illustrates a ReLU activation function that is performed by the activation function circuitry 600, according to an exemplary embodiment of the disclosure. In particular, the timing diagram 710-1 illustrates an exemplary linear ramp voltage V_{RAMP} 712-1 that is output from the ramp voltage generator circuit 620 over a given period from a ramp voltage start time (denoted T_{RAMP_START}) to a ramp voltage end time (denoted TRAMP END). In addition, the timing diagram 710-1 illustrates an exemplary conversion period (denoted T_{CONVERSION}) from a conversion start time (denoted T_{CON_START}) to a conversion end time (denoted TCON END).

As further shown in FIG. 7A, the linear ramp voltage V_{RAMP} 712-1 has an initial voltage level (denoted V_{RAMP} START) which is the same as a precharge voltage level 714 (denoted V_{PRECHARGE}) to which the capacitor 630 is precharged prior to the start of the conversion period. In some embodiments, as shown in FIG. 7A, the precharge voltage level 714 corresponds to the zero level MAC value (V_{OUT_0}). In this regard, prior to the conversion period, the capacitor voltage V_{CAP} is precharged to V_{OUT_0}.

To perform the ReLU computation operation, prior to the start of the conversion period, the output voltage V_{OUT} generated by the current integrator circuitry is applied to the input node N1 of the activation function circuitry 600, which causes the capacitor voltage V_{CAP} to either increase or decrease to V_{OUT}. For illustrative purposes, the timing diagram 710-1 illustrates a state in which the output voltage V_{OUT} is greater than the precharge voltage level 714 (zero-level MAC value V_{OUT_0}), such that a capacitor voltage V_{CAP} increases to a level that is greater than the precharge voltage level 714.

During the conversion period T_{CONVERSION}, the comparator circuit 610 continuously compares the capacitor voltage V_{CAP} to the linear ramp voltage V_{RAMP} 712-1, and generates an activation output signal AF_{OUT} 720-1 based on the result of the continuous comparison during the conversion period. In particular, FIG. 7A illustrates an exemplary activation output signal AF_{OUT} 720-1 that is generated under the exemplary voltage levels and timing conditions of the timing diagram 710-1. In particular, as shown in FIG. 7A, as the linear ramp voltage V_{RAMP} 712-1 increases from the initial ramp voltage level V_{RAMP_START}, the comparator circuit 610 is configured to output a logic 1 level (e.g., V_{DD}) during a period of time in which the linear ramp voltage V_{RAMP} 712-1 is less than V_{CAP}. As further shown in FIG. 7A, when the linear ramp voltage V_{RAMP} 712-1 reaches the capacitor voltage V_{CAP}, the comparator circuit 610 is configured to switch the output to a logic 0 level (e.g., GND), and remain at the logic 0 level (e.g., GND) during the remainder of the conversion period T_{CONVERSION} in which the linear ramp voltage V_{RAMP} 712-1 exceeds the stored capacitor voltage V_{CAP}.

In this configuration, the activation output signal AF_{OUT} 720-1 comprises a voltage pulse with a pulse duration P_{DURATION} that encodes the activation function output value based on the input value V_{OUT}. In instances where V_{OUT}≥V_{PRECHARGE} (indicating a zero or positive MAC input value), the activation output signal AF_{OUT} will comprise a voltage pulse with a pulse duration P_{DURATION} that encodes and corresponds to the zero or positive MAC value that is input to the ReLU activation function. The larger V_{OUT} is relative to V_{PRECHARGE}, the longer the pulse duration P_{DURATION} of the activation output signal AF_{OUT}. Ideally, when V_{OUT}=V_{PRECHARGE}=V_{RAMP_START}, the activation output signal AF_{OUT} will have a pulse duration P_{DURATION} of zero (0) as the output of the comparator circuit 610 will remain at logic level 0 (e.g., GND).

On the other hand, in instances where V_{OUT}<V_{PRECHARGE}=V_{RAMP_START} (indicating a negative MAC input value), the output of the comparator circuit 610 will remain at logic level 0, since the capacitor voltage V_{CAP} will be less than the linear ramp voltage V_{RAMP} 712-1 during the entire conversion period T_{CONVERSION}. For example, when V_{OUT}<V_{PRECHARGE}=V_{RAMP_START}, the capacitor voltage V_{CAP} will decrease from the precharge level V_{PRECHARGE} to the current integrator output level V_{OUT} such that V_{CAP} will be less than V_{RAMP_START} at the start T_{CON_START} of the conversion period T_{CONVERSION}.

In this regard, FIG. 7A illustrates an exemplary ReLU configuration of the activation function circuitry 600 in which (i) V_{PRECHARGE}=V_{RAMP_START}, (ii) the start time T_{CON_START} of the conversion period T_{CONVERSION} coincides with the start time T_{RAMP_START} of the linear ramp voltage V_{RAMP}, and (iii) the start voltage level V_{RAMP_START} of the linear ramp voltage V_{RAMP} 712 coincides with the zero-level output V_{OUT_0}. As such, the configuration of the activation function circuitry 600 as shown in FIG. 7A implements the exemplary ReLU function as shown in FIG. 5A where f(x)=x, when x≥0, and (ii) f(x)=0, when x<0.

In some embodiments, the duration of the ramp voltage (V_{RAMP_START} to V_{RAMP_END}) corresponds to, or otherwise coincides with the integration period T_{INT} for next layer of the artificial neural network. In particular, as the activation output signal AF_{OUT} 720-1 is generated and output from activation function circuitry of the neuron of a given neuron layer, the activation output signal AF_{OUT} 720-1 is input to the next synaptic device array and processed during the integration period T_{INT} to generate the activation data to the next downstream neuron layer.

It is to be noted that a clamped ReLU activation function can be implemented by a slight variation of the embodiment shown in FIG. 7A. For example, the end time T_{CON_END} of the conversion period T_{CONVERSION} can be reduced to limit the duration of the conversion period and thereby limit a maximum pulse duration of the activation output signal AF_{OUT}. In this embodiment, the activation output signal AF_{OUT} would comprise a voltage pulse with a maximum pulse duration P_{DURATION_MAX} which encodes the clamped ReLU output value that corresponds to the maximum voltage level V_{CEILING}. In all instances where V_{OUT}≥V_{CEILING}, the activation output signal AF_{OUT} output from the comparator circuit 610 will have the maximum pulse duration P_{DURATION_MAX}.

Next, FIG. 7B schematically illustrates operation the activation function circuitry 600 configured to implement a hard sigmoid activation function, according to an exemplary embodiment of the disclosure. FIG. 7B schematically illustrates a mapping 700 of output voltages V_{OUT} to a range of positive MAC values, a range of negative MAC values, and a zero MAC value, which is the same or similar to the mapping 700 discussed above in conjunction with FIG. 7A. Further, FIG. 7B depicts a timing diagram 710-2 which schematically illustrates a hard sigmoid activation function that is performed by the activation function circuitry 600, according to an exemplary embodiment of the disclosure.

In particular, the timing diagram 710-2 illustrates an exemplary linear ramp voltage V_{RAMP} 712-2 that is output from the ramp voltage generator circuit 620 over a given period from a ramp voltage start time T_{RAMP_START} to a ramp voltage end time T_{RAMP_END}. In addition, the timing diagram 710-2 illustrates an exemplary conversion period T_{CONVERSION} from a conversion start time T_{CON_START} to a conversion end time T_{CON_END}. The hard sigmoid implementation shown in the timing diagram 710-2 of FIG. 7B is configured by (i) setting a precharge voltage level 714 to be equal to the zero-level MAC input (V_{OUT_0}), (ii) setting a start voltage level V_{RAMP} START of the linear ramp voltage V_{RAMP} 712-2 to be equal to a negative voltage cutoff value (V⁻_{CUTOFF}) of the given hard sigmoid activation function, which is less than the zero-level MAC input (V_{OUT_0}), and (iii) setting the end time T_{CON_END} of the conversion period T_{CONVERSION} to coincide with a voltage level of the linear ramp voltage 712-2 which corresponds to a positive voltage cutoff value (V⁺_{CUTOFF}) of the given hard sigmoid activation function, which is greater than the zero-level voltage.

In this exemplary configuration, the activation output signal AF_{OUT} 720-2 shown in FIG. 7B comprises a voltage pulse with a pulse duration P_{DURATION_0} which encodes an output value of zero (0). In all instances where V_{CAP}=V_{OUT}≥V⁺_{CUTOFF}, the activation output signal AF_{OUT} 720-2 generated at the output of the comparator circuit 610 will have a maximum pulse duration P_{DURATION_MAX}. Further, in instances where V_{CAP}=V_{OUT}<V⁻_{CUTOFF}=V_{RAMP} START, the activation output signal AF_{OUT} will have a pulse duration P_{DURATION} of zero (0) since the output of the comparator circuit 610 will remain at logic level 0 (e.g., GND). In this configuration, a P_{DURATION} of zero (0) encodes the minimum input value of −1.0 which corresponds to the negative voltage cutoff V⁺_{CUTOFF} (e.g., value of −1.0).

In other embodiments, the activation function circuitry 600 can be configured to implement a hard tanh activation function (e.g., FIG. 5D) using the same or similar techniques for the activation functions as discussed above in conjunction with FIGS. 7A and 7B. In such embodiments, the activation function circuitry 600 would be configured with an additional comparator circuit and ramp voltage signal (e.g., −V_{RAMP}) to process negative voltage inputs (x) and generate corresponding negative activation value outputs, the details of which are readily understood by those of ordinary skill in the art based on the teachings disclosed herein.

Next, FIG. 7C schematically illustrates operation the activation function circuitry 600 configured to implement a linear activation function, according to an exemplary embodiment of the disclosure. FIG. 7C schematically illustrates a mapping 700 of output voltages V_{OUT} to a range of positive MAC values, a range of negative MAC values, and a zero MAC value, which is the same or similar to the mapping 700 discussed above in conjunction with FIGS. 7A and 7B. Further, FIG. 7C depicts a timing diagram 710-3 which schematically illustrates an exemplary implementation of a linear activation function that is performed by the activation function circuitry 600, according to an exemplary embodiment of the disclosure.

In particular, the timing diagram 710-3 illustrates an exemplary linear ramp voltage V_{RAMP} 712-3 that is output from the ramp voltage generator circuit 620 over a given period from a ramp voltage start time T_{RAMP_START} to a ramp voltage end time T_{RAMP_END}. In addition, the timing diagram 710-3 illustrates an exemplary conversion period T_{CONVERSION} from a conversion start time T_{CON_START} to a conversion end time T_{CON_END}. The linear activation function shown in the timing diagram 710-3 of FIG. 7C is configured by (i) setting a precharge voltage level 714 to be equal to the zero-level MAC input (V_{OUT_0}), (ii) setting a start voltage level V_{RAMP} START of the linear ramp voltage V_{RAMP} 712-3 to be equal to ground voltage GND, and having a maximum voltage of V_{DD} at the ramp signal end time T_{RAMP_END}, and (iii) setting the end time T_{CON_END} of the conversion period T_{CONVERSION} to coincide with a voltage level of the linear ramp voltage 712-3 which corresponds to the maximum output voltage V_{DD}, and which corresponds to the highest expected positive MAC value for the given application.

In this exemplary configuration, the activation output signal AF_{OUT} 720-3 shown in FIG. 7C comprises a voltage pulse with a pulse duration P_{DURATION_0} which encodes an output value of zero (0) for target MAC value input of zero (0). The exemplary timing diagram 710-3 illustrates that the output of the linear activation function will be equal to the MAC value input to the linear activation function over an entire range of GND to V_{DD}. In this regard, it is to be noted that the linear activation function of FIG. 7C is similar to the ReLU activation function of FIG. 7A with respect positive MAC values, but also provide linearity of the output for negative MAC input values. The linear activation function as shown in FIG. 7C can be utilized for readout in the analog RPU array when configured to perform, e.g., analog vector-matrix multiplication operations using for computational matrices for solving linear equations, etc.

As noted above, the analog RPU hardware (e.g., RPU array, peripheral circuitry, analog activation function circuitry, etc.) can suffer from many non-idealities including, but not limited to, mismatches in the hardware circuitry (e.g., mismatches in readout circuitry and/or hardware activation function circuitry), voltage offsets, current leakage, parasitic resistances, parasitic capacitances, parasitic voltage drops due to series resistance of row and column lines, write nonlinearity, etc., and other types of hardware offset errors. Such non-idealities of the analog RPU hardware result in variations of the output lines (e.g., column-to-column variations) which leads to significant errors in the hardware computations (e.g., matrix-vector multiply operations). The errors in the hardware computations lead to degradation and variation of the MAC results that are generated on the output lines (e.g., column lines), e.g., the columns of the RPU array exhibit different offsets, slopes, and/or spread in the MAC results that are output from the columns. Such degradation of the MAC results can have a significant impact on, e.g., the classification accuracy of an artificial neural network that is implemented by the analog RPU hardware.

For example, FIG. 8 graphically illustrates various line-to-line variations of an analog resistive memory crossbar array which can lead to degraded MAC computations, according to an exemplary embodiment of the disclosure. More specifically, FIG. 8 comprises a graph 800 which illustrates MAC distribution data for different column lines of an analog RPU crossbar array, including a first set of MAC distribution data 810 for a first column line, a second set of MAC distribution data 820 for a second column line, and a third set of MAC distribution data 830 for a third column line. The individual MAC values of each set of MAC distribution data are represented by small shaded circles. The graph 800 comprises a Y-axis which shows a range of actual MAC values, and an X-axis which shows a range of target MAC values. In the exemplary embodiment of FIG. 8, the actual MAC values are depicted in a range of 0 to 255 which represents, e.g., 256 discrete voltage levels in a range from GND to V_{DD}, such as discussed above in conjunction with FIG. 7. The target MAC values are depicted in an exemplary range from −6.0 to +6.0, and represent target software MAC values for a given application (which range of target MAC values can vary depending on the application).

In addition, FIG. 8 schematically illustrates that (i) the first set of MAC distribution data 810 is fitted to a first line 810-1, (ii) the second set of MAC distribution data 820 is fitted to second line 820-1, and (iii) the third set of MAC distribution data 830 is fitted to a third line 830-1. In some embodiments, the lines 810-1, 820-1, and 830-1 are computed (as part of analog crossbar array calibration process) using any suitable line fitting process for constructing a straight line that fits to a distribution of MAC data generated and output from a given column line of an RPU crossbar array. For example, a straight line (line of best fit) for a given set of MAC distribution data can be computed using a linear regression process, a least square method, and other similar methods known to those of ordinary skill in the art.

Further, FIG. 8 depicts a target diagonal line 840 which represents a target line for to which the MAC distribution data of each column line is aligned (or substantially aligned) as a result of performing an analog crossbar array calibration process. In an ideal case, the MAC computations for a given column line are determined as: MAC=ΣWx. In reality, the MAC computations for a given column line are determined as: MAC=αΣ(W+ε)x+γ, where α denotes a slope, where ε denotes spread, and where γ denotes an offset. As shown in FIG. 8, the different sets of MAC distribution data 810, 820, and 830 for the different column lines of the analog RPU crossbar array have different slopes, spreads, and offsets.

More specifically, as shown in FIG. 8, the target diagonal line 840 comprises an actual target offset 850 which corresponds to a point at which the target diagonal line 840 intersects a target MAC value of zero (0). In some embodiments, the actual target offset 850 is set to a value of 128. In addition, the different sets of MAC distribution data 810, 820, and 830 have respective actual offsets 851, 852, and 853, which correspond to the points at which the respective straight lines 810-1, 820-1, and 830-1 intersect the target MAC value of zero (0) (represented by a Y-intercept of line 860). In the exemplary illustration, the actual offset 851 of the first set of MAC distribution data 810 is greater than the actual target offset 850 of the target diagonal line 840 and the actual offsets 852 and 853 of the respective second set and third set of MAC distribution data 820 and 830. In addition, the actual offsets 852 and 853 of the respective second set and third set of MAC distribution data 820 and 830 are less than the actual target offset 850 of the target diagonal line 840. As explained in further detail below, an analog crossbar array calibration process is configured to reduce the column-to-column offset variation of an analog RPU crossbar array so that the MAC results computed for each column have a same or similar offset which corresponds to the actual target offset 850. As a result of the analog crossbar array calibration process, the different sets of MAC distribution data 810, 820, and 830 would be aligned or substantially aligned to the target diagonal line 840.

As further shown in FIG. 8, the target diagonal line 840 comprises target slope SL_{T}. The lines 810-1, 820-1, and 830-1 of the respective sets of MAC distribution data 810, 820, and 830 have respective slopes SL₁, SL₂, and SL₃. In the exemplary illustration, the slope SL₁ of the first line 810-1 is greater than the target slope SL_{T} of the target diagonal line 840 and the slopes SL₂ and SL₃ of the respective second and third lines 810-2 and 810-3. In addition, the slopes SL₂ and SL₃ of the respective second and third lines 810-2 and 810-3 are less than the target slope SL_{T} of the target diagonal line 840. As explained in further detail below, an analog crossbar array calibration process is configured to reduce the column-to-column slope variation of the analog RPU crossbar array so that the MAC distribution data computed for each column have a same or similar slope which corresponds to the target slope SL_{T} of the target diagonal line 840.

As further shown in FIG. 8, the different sets of MAC distribution data 810, 820, and 830 have different spreads. For a given MAC distribution, the spread provides a measure of how far individual MAC values tend to fall from the center of the distribution. The spread can be determined using any suitable method such as, e.g., computing the range (the distance between the highest and lowest value), or computing a variance, or standard deviation, using techniques well known to those of ordinary skill in the art. In some embodiments, the spread is determined by computing the variance, wherein the variance is a measure of how far a set of MAC values are spread out from their mean (average) value (e.g., average squared distance to the mean). The variance denotes an expected difference of deviation from the actual value.

In FIG. 8, the respective spreads for the different sets of MAC distribution data 810, 820, and 830 are schematically illustrated based on perpendicular distances from the MAC values to the respective straight lines 810-1, 810-2, and 810-3. In the exemplary illustration, the first set of MAC distribution data 810 has a spread that is greater than the spreads of the second set and third set of MAC distribution data 820 and 830. As explained in further detail below, an analog crossbar array calibration process is configured to reduce the spread of computed MAC values for each column of the analog RPU crossbar array.

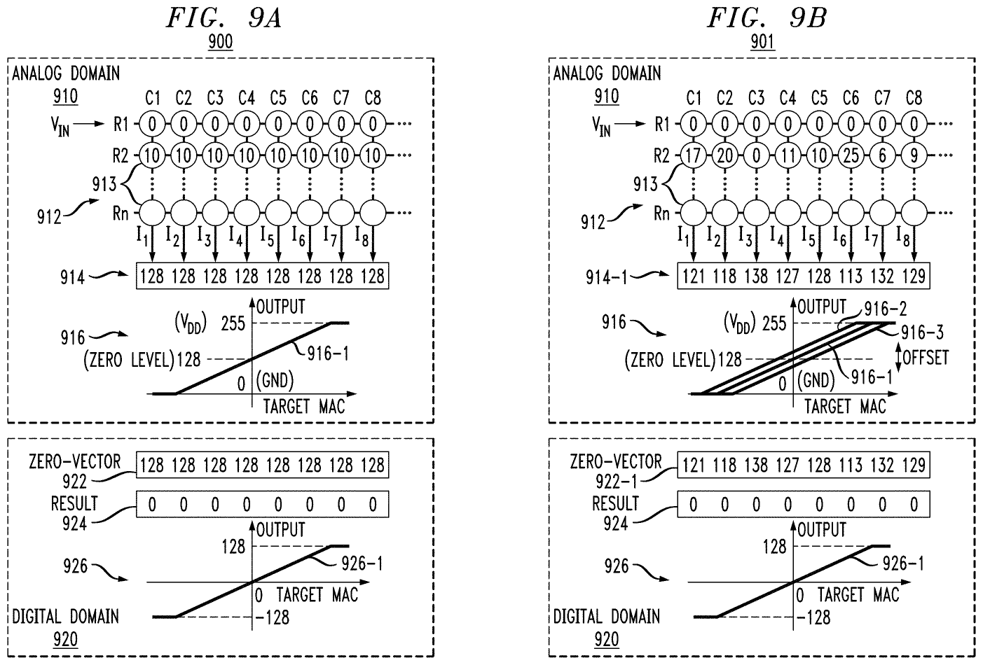

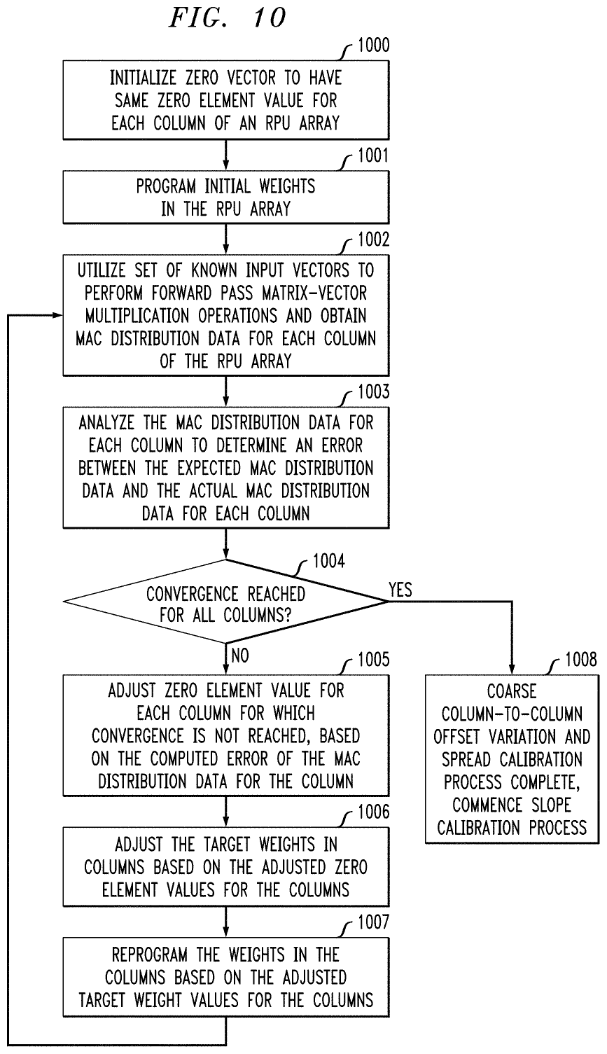

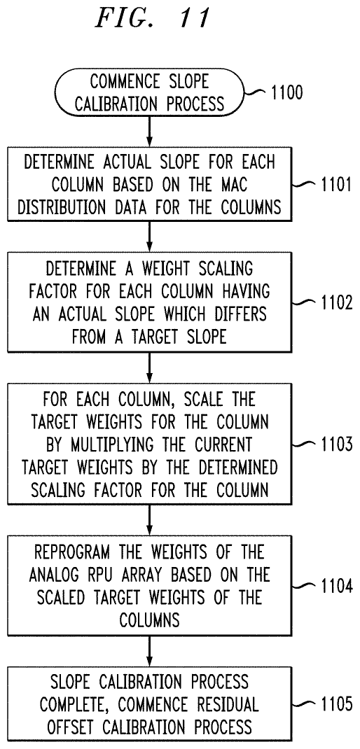

As noted above, an exemplary analog crossbar array calibration process is configured to reduce the offset variation between column lines) of a given analog RPU crossbar array, and to reduce the spread (e.g., variance) of MAC results that are output from each column line of the analog RPU crossbar array by performing an iterative process which involves adjusting a “zero vector” for the given analog RPU array and tuning the programmed weights of a weight matrix stored in the analog RPU crossbar array until a convergence criterion is achieved. For the purpose of introducing and explaining the concept of a “zero vector” for analog calibration, FIGS. 9A and 9B schematically illustrate a process of adjusting a “zero vector” and reprograming weights to compensate for column-to-column offset variation of a given analog RPU crossbar array, according to an exemplary embodiment of the disclosure.

More specifically, FIG. 9A schematically illustrates computations 900 that are performed in an analog domain 910 and a digital domain 920 in an ideal case in which there is no column-to-column offset variation of an RPU crossbar array. In particular, FIG. 9A schematically illustrates an exemplary analog RPU array 912 having rows R1, R2, . . . , Rn, and at least eight columns C1, C2, C3, C4, C5, C6, C7, and C8, etc., and an array of RPU cells 913, with each RPU cell 913 located at a cross-point between a given row line and given column line. For purposes of discussion, it is assumed that (i) each RPU cell 913 in the first row R1 is programed to have a weight value of zero (0), (ii) the possible output MAC values from the columns C1, C2, C3, C4, C5, C6, C7, and C8, etc., are in a range from 0 to 255 which represents, e.g., 256 discrete voltage levels in a range from GND to V_{DD}, and that (iii) the zero-level output is mapped to a MAC output value of 128, such as discussed above in conjunction with FIGS. 7 and 8.

FIG. 9A illustrates a read operation in which an input voltage V_{IN} is applied to only the first row R1 of the analog RPU array 912, which results in a MAC output vector 914 comprising MAC values of 128 output from the columns. In an ideal case, given that each RPU cell in the first row R1 comprises a zero (0) weight value, that MAC output from each column would be 128 (e.g., representing the zero-level output voltage V_{OUT}). FIG. 9A illustrates a graph 916 comprising a straight line 916-1 which represents a linear function of actual MAC output values (in the analog domain), wherein the straight line 916-1 comprises an actual offset value of 128 which corresponds to the point at which the straight line 916-1 intersects a target MAC value of zero (0). For the ideal case of FIG. 9A, the straight line 916-1 represents a linear function of actual MAC output values that could be output from each column C1-C8 for a single-row read operation of a given row of the analog RPU array 912, depending on the weight values of the RPU cells 913 within the given row.

In the digital domain 920, a digital processor (e.g., FPGA) would maintain a zero-vector 922 having a “zero element” for each column of the analog RPU array 912. In the ideal case of FIG. 9A, the zero element for each column would be set to 128. To compute a result vector 924 in the digital domain 920, the digital processor would subtract the zero-vector 922 from the MAC output vector 914. In the exemplary embodiment of FIG. 9A, the result vector 924 is shown to comprise a zero (0) value for each column given that each MAC value output of each column is 128. FIG. 9A illustrates a graph 926 comprising a straight line 926-1 which represents a linear function of actual MAC output values (in the digital domain), wherein the straight line 926-1 comprises an actual offset value of zero (0) which corresponds to the point at which the straight line 926-1 intersects a target MAC value of zero (0).

In the digital domain 920, the process of subtracting the zero-vector 922 from the MAC output vector 914 enables computation of actual MAC output values ranging from −128 to +128. For example, as further shown in FIG. 9A, assume that the RPU cells 913 in the second row R2 each have a programmed weight value of +10. For the single-row read out operation of the second row R2, each column C1-C8 would have an MAC output value of 138 (128+10) (i.e., the MAC output vector 914 would have a value of 138 for each column C1-C8). Given that zero-vector 922 includes values of 128 for each zero element associated with the columns C1-C8, subtracting the zero-vector 922 from the MAC output vector 914 yields MAC output values of +10 for each column C1-C8, in the digital domain 920.

It is to be understood that the programed weight values in the analog RPU array 912 can have negative values, zero values, or positive values. For example, in FIG. 9A, assume that the RPU cells 913 at the cross-point of the first row R1 and the columns C1 and C2 have programmed weight values of −10 and −5, respectively. For the readout operation shown in FIG. 9A, the first column C1 would have an MAC output value of 118 (128-10), and the second column C2 would have a MAC output value of 123 (128-5). Given that the zero-vector 922 comprises value of 128 for the zero elements associated with the first and second columns C1 and C2, subtracting the zero-vector 922 from the MAC output vector 914 yields MAC output values of −10 and −5.0 for the columns C1 and C2, respectively, in the digital domain 920.

Next, FIG. 9B schematically illustrates computations 901 that are performed in the analog domain 910 and the digital domain 920 in the case where there are column-to-column offset variations of the analog RPU array 912. In particular, FIG. 9B illustrates a situation in which the read operation (e.g., applying the input voltage V_{IN} to only the first row R1 of the analog RPU array 912) results in a MAC output vector 914-1 comprising MAC output values of 121, 118, 138, 127, 128, 113, 132, and 129 for respective columns C1, C2, C3, C4, C5, C6, C7, and C8. Despite that each RPU cell in the first row R1 comprises a zero (0) weight value, that MAC output values (of the MAC output vector 914-1) are different for different columns, which is an indication of column-to-column offset variation due to non-idealities of the analog RPU array 912.

For example, the graph 916 shown in FIG. 9B comprises the straight line 916-1 which represents a linear function of actual MAC output values (in the analog domain), wherein the straight line 916-1 comprises an actual offset value of 128 which corresponds to the point at which the straight line 916-1 intersects a target MAC value of zero (0). In this regard, the straight line 916-1 in FIG. 9B would represent the possible MAC output values for the fifth column C5, as the fifth column C5 is shown to have an output MA value of 128 (given the zero weight value of the RPU cell 913 at the cross-point of the first row R1 and the fifth column C5). In addition, the graph 916 comprises a straight line 916-2 which represents a linear function of actual MAC output values (in the analog domain) for a given column (e.g., the third column C3) having an actual offset value which is greater than 128 (e.g., 128) in the MAC output vector 914-1. Further, the graph 916 comprises a straight line 916-3 which represents a linear function of actual MAC output values (in the analog domain) for a given column (e.g., the second column C2) having an actual offset value which is less than 128 (e.g., 118) in the MAC output vector 914-1.

In the digital domain 920, the digital processor would adjust the zero elements of the zero-vector 922 (FIG. 9A) to generate a modified zero-vector 922-1 having zero element values of 121, 118, 138, 127, 128, 113, 132, and 129 for respective columns C1, C2, C3, C4, C5, C6, C7, and C8, as shown in FIG. 9B. In this instance, when computing the result vector 924 in the digital domain 920, the digital processor would subtract the modified zero-vector 922-1 from the MAC output vector 914-1, wherein the result vector 924 is shown to comprise a zero (0) value for each column, similar to FIG. 9A.

In the digital domain 920, the process of subtracting the zero-vector 922-1 from the MAC output vector 914-1 enables computation of target MAC output values ranging from −128 to +128. However, for programmed weights having non-zero values, the weights would have to be reprogramed based on the modified zero-vector 922-1. For example, assume that the RPU cells 913 in the second row R2 each have a programmed weight value of +10, such as shown in FIG. 9A. Based on the values of the zero elements of the modified zero-vector 922-1 of FIG. 9B, the RPU cells 913 in the second row R2 would be programmed to values of 17, 20, 0, 11, 10, 25, 6, and 9 for respective columns C1, C2, C3, C4, C5, C6, C7, and C8, respectively, to ensure that a single-row read operation of the second row R2 would result in in a MAC output vector comprising MAC output values of +138 corresponding to an effective weight of +10 for each RPU cell 913 in the second row R2. In the exemplary illustration of FIG. 9B, to obtain an effective weight value of +10 for each RPU cell 913 in the second row R2, the adjusted weight value (W_{adj}) for each RPU cell 913 would be determined as W_{adj}=138−Zₑₗ, wherein Zₑₗ denotes the zero element of the zero-vector 922-1 corresponding to a given column.

For example, the adjusted weight value of +17 for the RPU cell 913 at the cross-point of R2 and C1 is computed based on Zₑₗ=121 for the first column C1 (i.e., +17=138-121). Further, the adjusted weight value of +27 for the RPU cell 913 at the cross-point of R2 and C2 is computed based on Zₑₗ=118 for the second column C2 (i.e., +20=138-118). In addition, the adjusted weight value of 0 for the RPU cell 913 at the cross-point of R2 and C3 is computed based on Zₑₗ=138 for the third column C3 (i.e., 0=138-138). The adjusted weight values of 11, 25, 6 and 9 for of the RPU cells 913 at the cross-point of R2 and the respective columns C4, C6, C7, and C8, are similarly computed based on the respective Zₑₗ values of 127, 113, 132, and 129 for the columns C4, C6, C7, and C8. It is to be noted that the weight value of +10 for the RPU cell 913 at the cross-point of R2 and C5 is not adjusted, as the column C5 has a Zₑₗ value of 128 corresponding to the zero-level offset value of 128 in the analog domain 910, and the zero-level offset value of 0 in the digital domain 920.

As noted above, FIGS. 9A and 9B schematically illustrate general concepts of adjusting a “zero vector” and reprograming weights based on the adjusted zero vector to compensate for column-to-column offset variations of a given analog RPU crossbar array. In particular, in the exemplary illustration of FIG. 9B, for each column (e.g., C1, C2, C4, and C6) having an adjusted zero element which is less than the target zero level of 128 (zero offset), the weight values of 10 in the RPU cells 913 in the second row R2 which intersect the columns C1, C2, C4, and C6 are increased (made more positive) to counteract the lower column offsets of C1, C2, C4, and C6 relative to the target zero level of 128 (zero offset). On the other hand, for each column (e.g., C3, C7, and C8) having an adjusted zero element which is greater than the target zero level of 128 (zero offset), the weight values of 10 in the RPU cells 913 in the second row R2 which intersect the columns C3, C7, and C8 are decreased (made more negative) to counteract the higher column offsets of C1, C2, C4, and C6 relative to the target zero level of 128 (zero offset). In this regard, the weights of the analog RPU crossbar array are reprogrammed to effectively change the zero elements of the columns in the analog domain (and thus counteract column offset variation in the analog domain) based on the adjusted zero elements of the zero vector as determined in the digital domain.

The exemplary concepts shown in FIG. 9B of adjusting a zero vector and reprograming weights based on the adjusted zero vector to compensate for column-to-column offset variations of a given analog RPU crossbar array are utilized to implement the exemplary analog crossbar array calibration techniques as discussed herein. While FIG. 9B illustrates a calibration process with respect to a single row for purposes of illustration, an analog crossbar array calibration process according to an exemplary embodiment of the disclosure involve aligning the MAC distribution data of every output line (e.g., column line) of the analog RPU crossbar array to a target offset. Indeed, when all input lines (e.g., rows) of the analog RPU crossbar array are activated (e.g., to perform a forward pass inference operation using a hardware-implemented artificial neural network, or to perform a hardware accelerated computation operation such as a vector matrix multiply operation), all non-linearities and non-idealities of the analog RPU crossbar array hardware will affect the MAC results that are output on the output lines (e.g., columns). In this regard, it is not trivial to determine the target zero-element for each output line (e.g., column) for purposes of reprogramming the weights to adjust offset of MAC distribution data for each column to a target offset. In accordance with exemplary embodiments of the disclosure, one or more iterative processes (e.g., FIGS. 10 and 12) are implemented to reduce the column-to-column offset variation and converge the offset of each column to target offset.

FIG. 10 is a flow diagram of a method for calibrating an analog crossbar array according to an exemplary embodiment of the disclosure. More specifically, FIG. 10 illustrates an exemplary embodiment of the first calibration process 134-1 (FIG. 1) which implements an iterative method that involves adjusting a zero vector for the given analog RPU array and tuning the programmed weights of a weight matrix stored in the analog RPU array, to reduce the line-to-line offset variation and the spread of MAC distribution results, which are generated on output lines (e.g., column lines) of the analog RPU array. For purposes of illustration, the process flow of FIG. 10 will be discussed in the context of a calibration process that is performed for given analog RPU crossbar array (or RPU tile) which stores a given matrix W (e.g., computational matrix or synaptic weight matrix, etc.).

For example, in the context of a software application for solving matrix equations such as a linear system or an eigenvector equation, the RPU array would store a computational matrix W for performing hardware accelerated matrix computations such as vector-matrix multiplication operations. Further, in the context of a hardware-implemented artificial neural network, the analog RPU crossbar array would comprise an RPU array which stores a synaptic weight matrix W that provides weighted connections between two layers of artificial neurons the hardware artificial neural network (e.g., input layer and first hidden layer). It is to be understood that the same process flow of FIG. 10 would be applied for all analog RPU crossbar arrays that stored synaptic weight matrices of the artificial neural network.

Referring to FIG. 10, the calibration process involves initializing a zero vector (in the digital domain) for the given analog RPU crossbar array such the zero vector has a same zero element value for each output line (e.g., column line) of the analog RPU crossbar array (block 1000). For example, in some embodiments such as shown in FIG. 9A, the zero vector is initialized to have zero element values of 128 for each column line of the analog RPU cross bar array. As noted above, the initial zero element value of 128 corresponds target MAC value of zero (zero offset).

Next, the initial weights of a given weight matrix are programmed in the RPU array (block 1001). For example, in some embodiments, the neural core configuration process 132 (FIG. 1) receives a matrix of target weight values W_{T} which comprises an array of weight values computed in the digital domain, and performs, e.g., a row-wise parallel programming operation to program each row of the RPU array to store programmed weight values W_{P} which correspond to the target weight values W_{T}. The programmed weight values W_{P} are programmed based on the initial zero element values of the zero vector, such as discussed above in conjunction with FIG. 9A. In the context of an artificial neural network trained in the digital domain, each analog RPU crossbar array that is configured to implement an artificial synaptic device array for the trained artificial neural network would be initially programmed to include the respective learned synaptic weight matrix (matrix of target weight values W_{T}).

In some embodiments, a row-wise parallel programming operation involves performing a parallel write operation for each RPU cell in a given row Rᵢ by applying a time encoded pulse Xᵢ to an input of the given row Rᵢ, and applying voltage pulses Yⱼ with variable amplitudes to the column lines Cⱼ to thereby program each RPU cell at the cross-point of the given row Rᵢ and the columns With this programming process, a given weight Wᵢⱼ for a given RPU cell is programed by a multiplication operation Xi×Yⱼ that is achieved based on the respective time encoded and amplitude encoded pulses applied to each RPU cell, the details of which are known to those of ordinary skill in the art. With the programming process, the programmed weight values W_{P} are determined to be as accurate as possible to the corresponding target weight values W_{T}.

Once the analog RPU crossbars arrays for the hardware artificial neural network are programmed with the respective trained synaptic weight matrices, a first iteration of the calibration process is performed by applying a set of known input vectors to the hardware-implemented artificial neural network to perform forward pass inference operations (e.g., matrix-vector multiplication operations) and obtain MAC distribution data for each column line of the RPU array (block 1002). In some embodiments, the set of known input vector comprises a set of input vectors that were applied to the trained artificial neural network in the digital domain to obtain a corresponding set of known output vectors for each layer of the trained artificial neural network and, thus obtain a set of known (expected) MAC distribution data for each synaptic weight array output of each layer of the trained artificial neural network.

For purposes of obtaining MAC distribution data for each column of the given RPU array, the input vectors to the analog RPU crossbar array comprise the software input vectors that were input to the given layer in the digital domain, and the actual MAC distribution data is computed in hardware based on the software input vectors. In other words, the analog RPU array is analyzed and calibrated by applying software input values (as determined in the digital domain) to the layers of the hardware-implemented artificial neural network, and analyzing the actual MAC output results from the RPU arrays obtained based on the software input values.

For example, assume that a given trained artificial neural network comprises three neuron layers L1 (input layer), L2 (hidden layer), and L3 (output layer), and a first synaptic array S1 connecting L1 to L2, and a second synaptic array S2 connecting L2 to L3. For the analog calibration process, the known set of input vectors would be input to the first layer L1 of the hardware-implemented artificial neural network, and the resulting MAC distribution data output from a first analog RPU array implementing the first synaptic array S1 would be obtained and used for analysis and calibration of the first analog RPU array. In addition, the second layer L2 of the hardware-implemented artificial neural network would receive (as input) the software output data from the first layer L1 (as computed in the digital domain) and the resulting MAC distribution data output from a second analog RPU array implementing the second synaptic array S2 would be obtained and used for analysis and calibration of the second analog RPU array.

By utilizing the software inputs to obtain the MAC distribution data for analysis, the calibration process can compare the actual MAC distribution data generated by the analog RPU hardware for a given neural network layer against the expected (known) MAC distribution data obtained in the digital domain for the given neural network layer (based on the trained (target) weight values in the digital domain). In this regard, for a given analog RPU crossbar array, the calibration process will analyze the actual MAC distribution data generated for each column of the given RPU crossbar array based on the software inputs to thereby determine an error between the expected MAC distribution data for each column (which is known in the digital domain) and the actual MAC distribution data (block 1003).

In some embodiments, the actual MAC distribution data for each column of the given RPU crossbar array is analyzed (block 1003) to determine an offset of the MAC distribution data, as well the slope and spread of the actual MAC distribution data. The offset, slope, and spread of the actual MAC distribution data for each column can be determined using suitable techniques such as linear regression techniques, and other techniques, such as discussed above in conjunction with FIG. 8. For example, the actual MAC distribution data for each column can be analyzed to determine a line of best fit (straight line) that is the best approximation of the given set of MAC data. The determined line of best fit can be utilized to determine the slope (gradient) of the MAC distribution data, as well the offset (e.g., Y-intercept of line 860, FIG. 8) of the MAC distribution data.

For the first iteration of the calibration process, the actual MAC distribution data that is obtained from each column of the given RPU array is based on the initial programmed weights (in block 1001) that are determined based on the initial zero element values (for the columns) of the zero vector (for the given RPU crossbar array), and errors in the hardware-computed MAC data due to the non-idealities of the analog RPU hardware. This can lead to a significant column-to-column offset variations between the actual MAC distribution data for the columns of the given RPU crossbar array. For example, as discussed above, FIG. 8 schematically illustrates variations in the determined offsets 851, 852, and 853 of the respective sets of MAC distribution data 810, 820, and 830 for three different columns of a given RPU crossbar array, as well as deviations of the determined offsets 851, 852, and 853 with respect to the actual target offset 850.

In some embodiments, the error that is determined (in block 1003) for a given set of MAC distribution data for a given column of the analog RPU crossbar array comprises a difference measure between the determined (actual) offset of the MAC distribution data for the given column and a target offset, i.e., error=actual offset−target offset. For example, referring to the exemplary illustration of FIG. 8, the first set of MAC distribution data 810 for the first column comprises a determined (actual) offset 851 value which is greater than the actual target offset 850 value, which indicates that the hardware computed MAC values of the first set of MAC distribution data 810 are too high as a result of, e.g., non-idealities of the analog hardware causing the MAC results generated from the first column of the RPU array to have an undesired positive offset. In some embodiments, as discussed below, the calibration process will counteract the higher hardware offset of the computed MAC data for the first column by decreasing the weight values of the first column (i.e., making the weights more negative).

On the other hand, as shown in FIG. 8, the second set of MAC distribution data 820 for the second column comprises a determined (actual) offset 852 value which is less than the actual target offset 850, which indicates that the hardware computed MAC values of the second set of MAC distribution data 820 are too low as a result of, e.g., non-idealities of the analog hardware causing the MAC results generated from the first column of the RPU array to have an undesired negative offset. In this case, the calibration process will counteract the lower hardware offset of the computed MAC data for the second column by increasing the weight values of the second column (i.e., making the weights more positive).

Referring back to FIG. 10, a determination is made as to whether convergence to the target offset has been reached for all columns (block 1004). In some embodiments, convergence is determined by comparing the difference (error, err) between the target offset and the currently computed offsets of each column to an error threshold value E to determine whether or not the difference (err) exceeds the error threshold value E, e.g., to determine if err≤ϵ. The error threshold value E can be selected to be any desired value depending on the application. In this process, convergence is determined on a column-by-column basis to determine if the actual offset for a given column has converged to the target offset, wherein subsequent iterations of the calibration process of FIG. 10 are performed for columns which have not reached convergence.

If it is determined that convergence has not been reached for all columns (negative determination in block 1004), the calibration process proceeds by adjusting the zero element value (in the digital domain) for each column for which convergence has not been reached, based on the determined difference (error, err) between the target offset and the current offset of the given column (block 1005). For example, if the current MAC distribution data for a given column has an actual offset which is greater than the target offset, the zero element value for the given column will be decreased based on the magnitude of the determined error for the given column. On the other hand, if the current MAC distribution data for a given column has an actual offset which is less than the target offset, the zero element value for the given column will be increased based on the magnitude of the determined error. The amount to which the current zero element for a given column is increased or decreased for each interaction is based on the determined error and the type of numerical optimization process that is utilized to minimize error and reach convergence. The type of optimization process that is utilized is based on the fact that there is a linear relationship between the zero element and the offset. In some embodiments, the calibration process of FIG. 10 implements a Newton-Raphson method to adjust (increase or decrease) the zero element value for a given column line by a certain amount that is proportional to the determined error for the given column.

For each column having an adjusted zero element value (in block 1005), the calibration process proceeds by adjusting the target weight values for the columns based on the respective adjusted zero element values for the columns (block 1006). For example, if the zero element value for a given column is adjusted by increasing the zero element value, the target weight values of the given column will be increased. On the other hand, if the zero element value for a given column is adjusted by decreasing the zero element value, the target weight values of the given column will be decreased. In some embodiments, the target weight values for a given column will be adjusted (e.g., increased or decreased) by an amount that is proportional to the amount by which the zero element value for the given column is adjusted (increased or decrease).

The stored weight values (i.e., currently programmed weights) for a given column of the analog RPU array are reprogrammed based on the adjusted target weight values for the given column (block 1007). With this process, the reprogramming of the weights for a given column will effectively counteract the column offset which exists due to the non-idealities of the analog RPU hardware and effectively reduce the spread for the given column. In particular, the reprogramming of the weights for a given column to lower weight values (more negative than the previous programmed weights of the previous iteration) will effectively counteract (decrease) the column offset that arises due to the non-idealities of the analog RPU hardware, as well as effectively reduce the spread for the given column. In addition, the reprogramming of the weights for a given column to higher weight values (more positive than the previous programmed weights of the previous iteration) will effectively counteract (increase) the column offset that arises due to the non-idealities of the analog RPU hardware, as well as effectively reduce the spread for the given column.

The iterative calibration process continues with additional iterations (blocks 1002-1007) until the convergence criterion is reached in which the actual offset for all columns have converged to the target offset within a given error threshold (affirmative determination is block 1004) at which time the first calibration process is completed, and a second calibration process is commenced (FIG. 11) to calibrate the slope of each column (block 1008). It is to be noted that the iterative calibration process of FIG. 10 is configured to coarsely reduce the column-to-column offset variation to effectively counteract the column offsets that arise due to non-idealities of the analog RPU hardware and programming errors. While FIG. 10 implements an optimization process to minimize the error with respect to offset (e.g., difference between actual column offset and target offset), it has been determined that such optimization process also reduces the spread of the MAC distribution data obtained for each iteration of the calibration process, as the spread for a given column tends to decrease for each iteration as the target weights of the column are iteratively adjusted and reprogrammed to converge the actual offset of the given column to the target offset.

FIG. 11 is a flow diagram of a method for calibrating an analog crossbar array according to another exemplary embodiment of the disclosure. More specifically, FIG. 11 illustrates an exemplary embodiment of the second calibration process 134-2 (FIG. 1) to reduce the line-to-line slope variation of MAC distribution data, which are generated on output lines (e.g., column lines) of the analog RPU array. As noted above, while the first calibration process (FIG. 10) may result in reducing the column-to-column offset variation and reducing the spread, there may still exist a column-to-column slope variation between the column lines of the analog RPU array. In such circumstance, a slope calibration process is commenced (block 1100) to reduce the column-to-column slope variation between the column lines of the analog RPU array.

The slope calibration process involves determining an actual slope for each column line using the MAC distribution data that is obtained for each column (block 1101). Iₙ some embodiments, the MAC distribution data that is used to determine the slope for each column includes the MAC distribution data that was obtained for each column of the analog RPU array for the last iteration of the offset/spread calibration process of FIG. 10. In other embodiments, the MAC distribution data for each column of an RPU analog array is obtained using the process discussed above in conjunction with block 1002 of FIG. 10. In some embodiments, the slope of a given column line is determined by fitting the MAC distribution data of the given column to a best fit straight line using a linear regression process, and determining a slope of the best fit straight line, such as discussed above in conjunction with FIG. 8.

Next, the slope calibration process proceeds to determine a weight scaling factor for each column having a determined slope which differs from a target slope (block 1102). For example, in the illustrative embodiment of FIG. 8, the target diagonal line 840 comprises a target slope SL_{T}, and the best fit straight lines 810-1, 820-1, and 830-1 of the respective sets of MAC distribution data 810, 820, and 830 (for the three different columns) have respective slopes SL₁, SL₂, and SL₃, which differ from the target slope SL_{T}. In some embodiments, the weight scaling factor is computed as follows: target slope=actual slope×weight scaling factor or weight scaling factor=(target slope)/(actual slope).

For each column having an actual slope which differs from the target slope, the slope calibration process proceeds by adjusting the target weight values for the column based on the respective weight scaling factor for the column (block 1103). In some embodiments, the adjusted target weight values for a given column are computed by multiplying (scaling) the target weight values (which exist at the completion of the first calibration process of FIG. 10) by the weight scaling factor for the given column.

The stored weight values (i.e., currently programmed weights) for a given column of the analog RPU array are reprogrammed based on the scaled target weight values for the given column (block 1104). With this process, the scaling of the weights for a given column will effectively reduce the column-to-column slope variation which exists due to the non-idealities of the analog RPU hardware, and align the slope of the MAC distribution data for the given columns to the target slope. In some embodiments, such as shown in FIG. 11, the slope calibration process comprises a single iteration and weight reprogramming operation. In other embodiments, at least one addition iteration of the slope calibration process can be performed to ensure that the actual slopes of the columns are aligned (or at least substantially aligned) to each other and to the target slope. Upon completion of the slope calibration process, the calibration process may proceed with a residual offset calibration process (block 1105).

For example, FIG. 12 is a flow diagram of a method for calibrating an analog crossbar array according to another exemplary embodiment of the disclosure. More specifically, FIG. 12 illustrates an exemplary embodiment of the third calibration process 134-3 (FIG. 1) to reduce residual line-to-line offset variation of MAC distribution data, which are generated on output lines (e.g., column lines) of the analog RPU array. As noted above, while the first calibration process (FIG. 10) may result in reducing the column-to-column offset variation and reducing the spread, there may still exist a relatively small amount (residual) of column-to-column slope variation between the column lines of the analog RPU array. In such circumstance, a residual offset calibration process is commenced (block 1200) to reduce or substantially eliminate residual column-to-column offset variation between the column lines of the analog RPU array.

The residual offset calibration process of FIG. 12 is similar to the offset/spread calibration process of FIG. 10, except that the residual offset calibration process of FIG. 12 reduces residual offset by adjusting bias weight values of RPU cells in the analog RPU array which store the bias weights, separate from the RPU cells in the analog RPU array which store the actual matrix weight values. As noted above, when a given analog RPU array configures the rows lines for input and the column lines for output, the given analog RPU array can have one or more rows of bias weights (denoted bias rows) depending on the size of the weight matrix (e.g., for a weight matrix with a size of 512×512, the analog RPU array can have 8 additional rows of bias weights which are interspersed between the rows of matrix weights, where one bias row is disposed every 63 rows of matrix weights). The bias weights are utilized to counteract any residual column offset which arise due to non-idealities of the analog RPU hardware by rigidly and finely adjusting (up or down) the offset of the computed MAC distribution data that is output from each column of the analog RPU array.

The residual offset calibration process comprises programming the initial bias weights in the bias rows of the analog RPU array based on initial target bias weights (block 1201). In some embodiments, the initial target bias weights are programmed to a bias weight value of zero (0). In some embodiments, the initial target bias weights are programmed during the first calibration process (e.g., block 1001, FIG. 10), but where the bias rows are not activated or otherwise utilized to collect the MAC distribution data for each column during the first offset/spread calibration process.

Next, a first iteration of the residual offset calibration process is performed by utilizing/applying the set of known input vectors to the hardware-implemented artificial neural network to perform forward pass inference operations (e.g., matrix-vector multiplication operations) and obtain MAC distribution data for each column line of the RPU array (block 1202). This process (block 1202) is similar to the process (block 1002) of the offset/spread calibration process (FIG. 10), the detail of which will not be repeated. However, for the residual offset calibration process, the bias rows are activated and an input voltage of 1 is applied to the input lines of the bias rows for the purpose of utilizing the bias weights to fine-tune adjust the offset of the MAC distribution data obtained from the columns.

Next, the residual offset calibration process will analyze the actual MAC distribution data generated for each column of the given RPU crossbar array based on the software inputs to thereby determine an error between the expected MAC distribution data for each column (which is known in the digital domain) and the actual MAC distribution data (block 1203). This process (block 1203) is similar to the process (block 1003) of the offset/spread calibration process (FIG. 10), the details of which will not be repeated. For the residual offset calibration process, it assumed that any error between the actual offset and the target offset will be relatively small as a result of performing the initial (coarse) offset calibration process (FIG. 10).

A determination is made as to whether convergence to the target offset has been reached for all columns (block 1204). In some embodiments, similar to the first offset/spread calibration process (block 1004, FIG. 10), convergence is determined by comparing the difference (error, err) between the target offset and the currently computed offsets of each column to an error threshold value ϵ to determine whether or not the difference (err) exceeds the error threshold value E, e.g., to determine if err≤ϵE. For the residual offset calibration process, the error threshold value ϵ can be selected to be smaller than the error threshold value ϵ used in the offset/spread calibration process. In this process, convergence is determined on a column-by-column basis to determine if the actual offset for a given column has converged to the target offset, wherein subsequent iterations of the calibration process of FIG. 12 are performed for columns which have not reached convergence.

If it is determined that convergence has not been reached for all columns (negative determination in block 1204), the residual offset calibration process proceeds by adjusting one or more target bias weights for each column for which convergence has not been reached, based on the determined difference (error, err) between the target offset and the current offset of the given column (block 1205). For example, if the current MAC distribution data for a given column has an actual offset which is greater than the target offset, one or more target bias weights for the given column will be decreased based on the magnitude of the determined error for the given column. On the other hand, if the current MAC distribution data for a given column has an actual offset which is less than the target offset, one or more target bias widths for the give column will be increased based on the magnitude of the determined error. The amount to which the one or more target bias weights of a given column is increased or decreased for each iteration is based on the determined error and the type of numerical optimization process that is utilized to minimize error and reach convergence. The type of optimization process that is utilized is based on the fact that there is a linear relationship between the bias weight values and the column offset. In some embodiments, the calibration process of FIG. 12 implements the same method, e.g., a Newton-Raphson method, as the first offset/spread calibration process to adjust (increase or decrease) the target bias weight values for one or more targe weights of a given column by a certain amount that is proportional to the determined error for the given column.

For each column having adjusted target bias weights, the residual offset calibration process proceeds by reprogramming the bias weights in the columns based on the adjusted target bias weight values for the given column (block 1206). With this process, the reprogramming of the bias weights for a given column will effectively counteract the residual column offset which exists due to the non-idealities of the analog RPU hardware for the given column. In particular, the reprogramming of one or more bias weights for a given column to lower bias weight values (more negative than the previous programmed bias weights of the previous iteration) will effectively counteract (decrease) the residual column offset that arises due to the non-idealities of the analog RPU hardware. In addition, the reprogramming of the one or more bias weights for a given column to higher bias weight values (more positive than the previous programmed bias weights of the previous iteration) will effectively counteract (increase) the residual column offset that arises due to the non-idealities of the analog RPU hardware for the given column.

The iterative residual offset calibration process continues with additional iterations (blocks 1202-1206) until the convergence criterion is reached in which the actual residual offset for all columns have converged to the target offset within a given error threshold (affirmative determination is block 1204) at which time the residual offset calibration process is complete (block 1207.

Exemplary embodiments of the present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

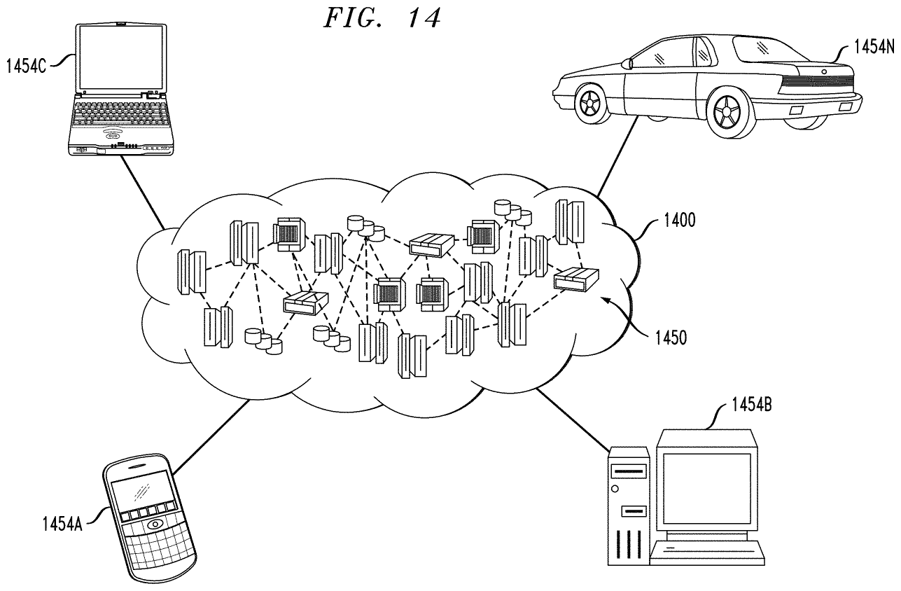

These concepts are illustrated with reference to FIG. 13, which schematically illustrates an exemplary architecture of a computing node that can host the computing system of FIG. 1, according to an exemplary embodiment of the disclosure. FIG. 13 illustrates a computing node 1300 which comprises a computer system/server 1312, which is operational with numerous other general purpose or special purpose computing system environments or configurations. Examples of well-known computing systems, environments, and/or configurations that may be suitable for use with computer system/server 1312 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 1312 may be described in the general context of computer system executable instructions, such as program modules, being executed by a computer system. Generally, program modules may include routines, programs, objects, components, logic, data structures, and so on that perform particular tasks or implement particular abstract data types. Computer system/server 1312 may be practiced in distributed cloud computing environments where tasks are performed by remote processing devices that are linked through a communications network. In a distributed cloud computing environment, program modules may be located in both local and remote computer system storage media including memory storage devices.

In FIG. 13, computer system/server 1312 in computing node 1300 is shown in the form of a general-purpose computing device. The components of computer system/server 1312 may include, but are not limited to, one or more processors or processing units 1316, a system memory 1328, and a bus 1318 that couples various system components including system memory 1328 to the processors 1316.

The bus 1318 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

The computer system/server 1312 typically includes a variety of computer system readable media. Such media may be any available media that is accessible by computer system/server 1312, and it includes both volatile and non-volatile media, removable and non-removable media.

The system memory 1328 can include computer system readable media in the form of volatile memory, such as random-access memory (RAM) 1330 and/or cache memory 1332. The computer system/server 1312 may further include other removable/non-removable, volatile/nonvolatile computer system storage media. By way of example only, storage system 1334 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1318 by one or more data media interfaces. As depicted and described herein, memory 1328 may include at least one program product having a set (e.g., at least one) of program modules that are configured to carry out the functions of embodiments of the invention.

The program/utility 1340, having a set (at least one) of program modules 1342, may be stored in memory 1328 by way of example, and not limitation, as well as an operating system, one or more application programs, other program modules, and program data. Each of the operating system, one or more application programs, other program modules, and program data or some combination thereof, may include an implementation of a networking environment. Program modules 1342 generally carry out the functions and/or methodologies of embodiments of the disclosure as described herein.

Computer system/server 1312 may also communicate with one or more external devices 1314 such as a keyboard, a pointing device, a display 1324, etc., one or more devices that enable a user to interact with computer system/server 1312, and/or any devices (e.g., network card, modem, etc.) that enable computer system/server 1312 to communicate with one or more other computing devices. Such communication can occur via Input/Output (I/O) interfaces 1322. Still yet, computer system/server 1312 can communicate with one or more networks such as a local area network (LAN), a general wide area network (WAN), and/or a public network (e.g., the Internet) via network adapter 1320. As depicted, network adapter 1320 communicates with the other components of computer system/server 1312 via bus 1318. It should be understood that although not shown, other hardware and/or software components could be used in conjunction with computer system/server 1312. Examples, include, but are not limited to: microcode, device drivers, redundant processing units, external disk drive arrays, RAID systems, SSD drives, and data archival storage systems, etc.

Additionally, it is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

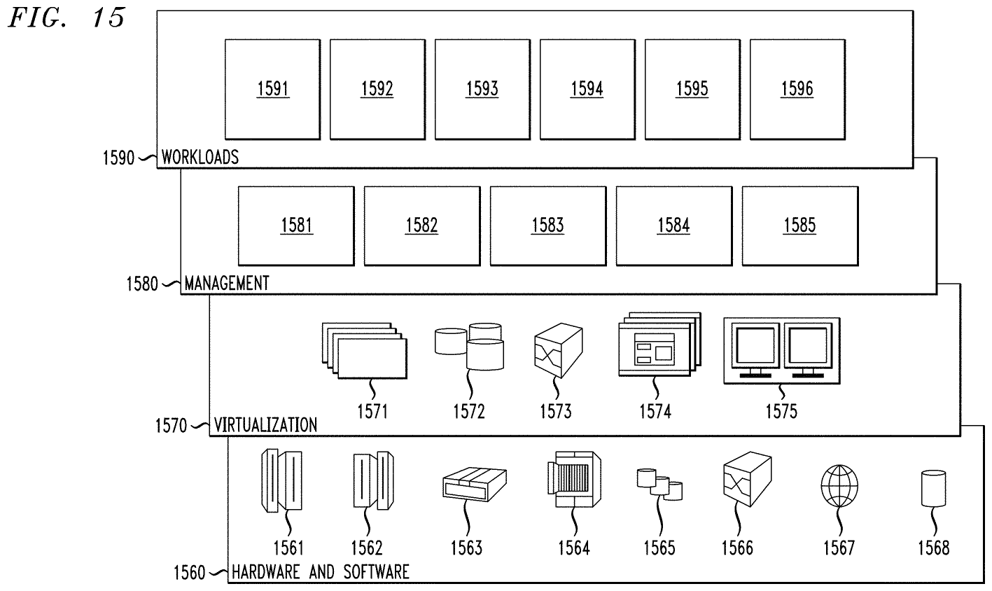

Referring now to FIG. 14, illustrative cloud computing environment 1400 is depicted. As shown, cloud computing environment 1400 includes one or more cloud computing nodes 1450 with which local computing devices used by cloud consumers, such as, for example, personal digital assistant (PDA) or cellular telephone 1454A, desktop computer 1454B, laptop computer 1454C, and/or automobile computer system 1454N may communicate. Nodes 1450 may communicate with one another. They may be grouped (not shown) physically or virtually, in one or more networks, such as Private, Community, Public, or Hybrid clouds as described hereinabove, or a combination thereof. This allows cloud computing environment 1400 to offer infrastructure, platforms and/or software as services for which a cloud consumer does not need to maintain resources on a local computing device. It is understood that the types of computing devices 1454A-N shown in FIG. 14 are intended to be illustrative only and that computing nodes 1450 and cloud computing environment 1400 can communicate with any type of computerized device over any type of network and/or network addressable connection (e.g., using a web browser).

Referring now to FIG. 15, a set of functional abstraction layers provided by cloud computing environment 1400 (FIG. 14) is shown. It should be understood in advance that the components, layers, and functions shown in FIG. 15 are intended to be illustrative only and embodiments of the invention are not limited thereto. As depicted, the following layers and corresponding functions are provided:

Hardware and software layer 1560 includes hardware and software components. Examples of hardware components include: mainframes 1561; RISC (Reduced Instruction Set Computer) architecture based servers 1562; servers 1563; blade servers 1564; storage devices 1565; and networks and networking components 1566. In some embodiments, software components include network application server software 1567 and database software 1568.

Virtualization layer 1570 provides an abstraction layer from which the following examples of virtual entities may be provided: virtual servers 1571; virtual storage 1572; virtual networks 1573, including virtual private networks; virtual applications and operating systems 1574; and virtual clients 1575.

In one example, management layer 1580 may provide the functions described below. Resource provisioning 1581 provides dynamic procurement of computing resources and other resources that are utilized to perform tasks within the cloud computing environment. Metering and Pricing 1582 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 1583 provides access to the cloud computing environment for consumers and system administrators. Service level management 1584 provides cloud computing resource allocation and management such that required service levels are met. Service Level Agreement (SLA) planning and fulfillment 1585 provide pre-arrangement for, and procurement of, cloud computing resources for which a future requirement is anticipated in accordance with an SLA.

Workloads layer 1590 provides examples of functionality for which the cloud computing environment may be utilized. Examples of workloads and functions which may be provided from this layer include: mapping and navigation 1591; software development and lifecycle management 1592; virtual classroom education delivery 1593; data analytics processing 1594; transaction processing 1595; and various functions 1596 for performing the software and hardware computations based on the exemplary methods and functions discussed above in conjunction with, e.g., FIGS. 1A, 1B, 3, 4, and FIGS. 10-12, for calibrating analog RPU systems that store one or more matrices (e.g., synaptic weight matrices or computational matrices) which are used for performing inference/classification using hardware-implemented artificial neural networks, solving linear systems using hardware accelerated matrix computations, etc. Furthermore, in some embodiments, the hardware and software layer 1560 would include, e.g., the computing system 100 of FIG. 1, the RPU compute node 200 of FIG. 2, etc., to implement or otherwise support the various workloads and functions 1596 for performing such hardware accelerated computing (e.g., hardware-based AI computing), analog in-memory computations, etc.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system, comprising:
a processor; and
a resistive processing unit array coupled to the processor, the resistive processing unit array comprising an array of cells, the cells respectively comprising resistive memory devices which are programable to store weight values;
wherein the processor is configured to:
obtain a matrix comprising target weight values;
program cells of the array of cells to store weight values in the resistive processing unit array, which correspond to respective target weight values of the matrix; and
perform a calibration process to calibrate the resistive processing unit array, wherein the calibration process comprises iteratively adjusting the target weight values of the matrix, and reprogramming the stored weight values of the matrix in the resistive processing unit array based on the respective adjusted target weight values, to reduce a variation between output lines of the resistive processing unit array with respect to multiply-and-accumulate distribution data that is generated and output from respective output lines of the resistive processing unit array during the calibration process.

2. The system of claim 1, wherein in performing the calibration process, the processor is configured to converge respective offsets of the multiply-and-accumulate distribution data, which are output from respective output lines, to a target offset.

3. The system of claim 1, wherein in performing the calibration process, the processor is configured to converge respective slopes of the multiply-and-accumulate distribution data, which are output from the respective output lines, to a target slope.

4. The system of claim 1, wherein in performing the calibration process, the processor is configured to reduce respective spreads of the multiply-and-accumulate distribution data, which are output from the respective output lines.

5. The system of claim 1, wherein in performing the calibration process, the processor is configured to:
apply a set of known input vectors to the resistive processing unit array to generate a set of multiply-and-accumulate distribution data for each output line, which result from performing analog multiplication operations by multiplying each of the known input vectors by the matrix in the resistive processing unit array;
determine, for a given output line of the resistive processing unit array, an offset associated with the generated set of multiply-and-accumulate distribution data for the given output line;
determine, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target weight values of the matrix;
adjust the target weight values of the matrix, which correspond to the stored weight values of the given output line, to counteract the error between the determined offset and the target offset; and
reprogram the stored weight values of the given output line of the resistive processing unit array based on the adjusted target weight values.

6. The system of claim 1, wherein in performing the calibration process, the processor is configured to:
apply a set of known input vectors to the resistive processing unit array to generate a set of multiply-and-accumulate distribution data for each output line, which result from performing analog multiplication operations by multiplying each of the known input vectors by the matrix in the resistive processing unit array;
determine, for a given output line of the resistive processing unit array, a slope of a straight line fitted to the generated set of multiply-and-accumulate distribution data for the given output line;
determine, for the given output line, a weight scaling factor based on a difference between the determined slope of the straight line fitted to the generated set of multiply-and-accumulate distribution data for the given output line, and a target slope of a straight line filled to a known set of multiply-and-accumulate distribution data that is obtained by performing a digital analog vector-matrix multiplication operation using the known input vectors and the target weight values of the matrix;
scale the target weight values of the matrix, which correspond to the stored weight values of the given output line, based on weight scaling factor; and
reprogram the stored weight values of the given output line of the resistive processing unit array based on the scaled target weight values.

7. The system of claim 1, wherein in performing the calibration process, the processor is configured to:
apply a set of known input vectors to the resistive processing unit array to generate a set of multiply-and-accumulate distribution data for each output line, which result from performing analog multiplication operations by multiplying each of the known input vectors by the matrix in the resistive processing unit array;
determine, for a given output line of the resistive processing unit array, an offset associated with the generated set of multiply-and-accumulate distribution data for the given output line;
determine, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target weight values of the matrix;
adjust one or more target bias weight values, which correspond to one or more stored bias weights of the given output line, to counteract the error between the determined offset and the target offset; and
reprogram the one or more stored bias weights of the given output line of the resistive processing unit array, based on the adjusted target bias weight values.

8. The system of claim 1, wherein the obtained matrix comprises one of a computational matrix utilized to perform matrix computations for a linear system, and a trained synaptic weight matrix of a trained artificial neural network to perform inference processing.

9. A computer program product, comprising:
one or more computer readable storage media, and program instructions collectively stored on the one or more computer readable storage media, the program instructions comprising:
program instructions to obtain a matrix comprising target weight values;
program instructions to program an array of cells of a resistive processing unit array to store weight values which correspond to respective target weight values of the matrix; and
program instructions to perform a calibration process to calibrate the resistive processing unit array, wherein the calibration process comprises iteratively adjusting the target weight values of the matrix, and reprogramming the stored weight values of the matrix in the resistive processing unit array based on the respective adjusted target weight values, to reduce a variation between output lines of the resistive processing unit array with respect to multiply-and-accumulate distribution data that is generated and output from respective output lines of the resistive processing unit array during the calibration process.

10. The computer program product of claim 9, wherein the program instructions for performing the calibration process comprise program instructions for converging respective offsets of the multiply-and-accumulate distribution data, which are output from respective output lines, to a target offset.

11. The computer program product of claim 9, wherein the program instructions for performing the calibration process comprise program instructions for converging respective slopes of the multiply-and-accumulate distribution data, which are output from the respective output lines, to a target slope.

12. The computer program product of claim 9, wherein the program instructions for performing the calibration process comprise program instructions for reducing respective spreads of the multiply-and-accumulate distribution data, which is output from the respective output lines.

13. The computer program product of claim 9, wherein the program instructions for performing the calibration process comprise:
program instructions for applying set of known input vectors to the resistive processing unit array to generate a set of multiply-and-accumulate distribution data for each output line, which result from performing analog multiplication operations by multiplying each of the known input vectors by the matrix in the resistive processing unit array;
program instructions for determining, for a given output line of the resistive processing unit array, an offset associated with the generated set of multiply-and-accumulate distribution data for the given output line;
program instructions for determining, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target weight values of the matrix;
program instruction for adjusting the target weight values of the matrix, which correspond to the stored weight values of the given output line, to counteract the error between the determined offset and the target offset; and
program instructions for reprogramming the stored weight values of the given output line of the resistive processing unit array based on the adjusted target weight values.

14. The computer program product of claim 9, wherein the program instructions for performing the calibration process comprise:
program instructions for applying set of known input vectors to the resistive processing unit array to generate a set of multiply-and-accumulate distribution data for each output line, which result from performing analog multiplication operations by multiplying each of the known input vectors by the matrix in the resistive processing unit array;
program instructions for determining, for a given output line of the resistive processing unit array, a slope of a straight line fitted to the generated set of multiply-and-accumulate distribution data for the given output line;
program instructions for determining, for the given output line, a weight scaling factor based on a difference between the determined slope of the straight line fitted to the generated set of multiply-and-accumulate distribution data for the given output line, and a target slope of a straight line filled to a known set of multiply-and-accumulate distribution data that is obtained by performing a digital analog vector-matrix multiplication operation using the known input vectors and the target weight values of the matrix;
program instructions for scaling the target weight values of the matrix, which correspond to the stored weight values of the given output line, based on weight scaling factor; and
program instructions for reprogramming the stored weight values of the given output line of the resistive processing unit array based on the scaled target weight values.

15. The computer program product of claim 9, wherein the program instructions for performing the calibration process comprise:
program instructions for applying set of known input vectors to the resistive processing unit array to generate a set of multiply-and-accumulate distribution data for each output line, which result from performing analog multiplication operations by multiplying each of the known input vectors by the matrix in the resistive processing unit array;
program instructions for determining, for a given output line of the resistive processing unit array, an offset associated with the generated set of multiply-and-accumulate distribution data for the given output line;
program instructions for determining, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target weight values of the matrix;
program instructions for adjusting one or more target bias weight values, which correspond to one or more stored bias weights of the given output line, to counteract the error between the determined offset and the target offset; and
program instructions for reprogramming the one or more stored bias weights of the given output line of the resistive processing unit array, based on the adjusted target bias weight values.

16. The computer program product of claim 9, wherein the obtained matrix comprises one of a computational matrix which is utilized to perform matrix computations for a linear system, and a trained synaptic weight matrix of a trained artificial neural network to perform inference processing.

17. A system, comprising:
a neuromorphic computing system comprising a resistive processing unit array which comprises an array of resistive processing unit cells, a plurality of input lines extending in a first direction across the resistive processing unit array, a plurality of output lines extending in a second direction across the resistive processing unit array, wherein each resistive processing unit cell is coupled at an intersection of one of the input lines and one of the output lines, and wherein the resistive processing unit cells respectively comprises resistive memory devices which are programable to store weight values;
a digital processing system, coupled to the neuromorphic computing system, wherein the digital processing system comprises one or more processors, and memory to store program instructions that are executed by the one or more processors to configure the digital processing system to control operations the neuromorphic computing system, wherein the digital processing system is configured to:
train an artificial neural network in a digital domain, wherein the trained artificial neural network comprises at least one trained synaptic weight matrix with target synaptic weight values that are learned;
program the array of resistive processing unit cells to store synaptic weight values which correspond to respective target synaptic weight values of the trained synaptic weight matrix; and
perform a calibration process to calibrate the resistive processing unit array, wherein the calibration process comprises iteratively adjusting the target synaptic weight values of the trained synaptic weight matrix, and reprogramming the stored synaptic weight values of the synaptic weight matrix in the resistive processing unit array based on the respective adjusted target synaptic weight values, to reduce a variation between output lines of the resistive processing unit array with respect to multiply-and-accumulate distribution data that is generated and output from respective output lines of the resistive processing unit array during the calibration process.

18. The system of claim 17, wherein in performing the calibration process, the digital processing system is configured to:
converge respective offsets of the multiply-and-accumulate distribution data, which are output from respective output lines, to a target offset; and
converge respective slopes of the multiply-and-accumulate distribution data, which are output from the respective output lines, to a target slope.

19. The system of claim 17, wherein in performing the calibration process, the digital processing system is configured to:
apply set of known input vectors to the resistive processing unit array to generate a set of multiply-and-accumulate distribution data for each output line, which result from performing analog multiplication operations by multiplying each of the known input vectors by the synaptic weight matrix in the resistive processing unit array;
determine, for a given output line of the resistive processing unit array, an offset associated with the generated set of multiply-and-accumulate distribution data for the given output line;
determine, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target synaptic weight values of the synaptic weight matrix;
adjust the target synaptic weight values of the synaptic weight matrix, which correspond to the stored synaptic weight values of the given output line, to counteract the error between the determined offset and the target offset; and
reprogram the stored synaptic weight values of the given output line of the resistive processing unit array based on the adjusted target weight values.

20. The system of claim 17, wherein in performing the calibration process, the digital processing system is configured to:
apply set of known input vectors to the resistive processing unit array to generate a set of multiply-and-accumulate distribution data for each output line, which result from performing analog multiplication operations by multiplying each of the known input vectors by the synaptic weight matrix in the resistive processing unit array;
determine, for a given output line of the resistive processing unit array, a slope of a straight line fitted to the generated set of multiply-and-accumulate distribution data for the given output line;
determine, for the given output line, a weight scaling factor based on a difference between the determined slope of the straight line fitted to the generated set of multiply-and-accumulate distribution data for the given output line, and a target slope of a straight line filled to a known set of multiply-and-accumulate distribution data that is obtained by performing a digital analog vector-matrix multiplication operation using the known input vectors and the target synaptic weight values of the synaptic weight matrix;
scale the target synaptic weight values of the synaptic weight matrix, which correspond to the stored synaptic weight values of the given output line, based on weight scaling factor; and
reprogram the stored synaptic weight values of the given output line of the resistive processing unit array based on the scaled target synaptic weight values.

21. The system of claim 17, wherein in performing the calibration process, the digital processing system is configured to:
apply set of known input vectors to the resistive processing unit array to generate a set of multiply-and-accumulate distribution data for each output line, which result from performing analog multiplication operations by multiplying each of the known input vectors by the synaptic weight matrix in the resistive processing unit array;
determine, for a given output line of the resistive processing unit array, an offset associated with the generated set of multiply-and-accumulate distribution data for the given output line;
determine, for the given output line, an error between the determined offset of the generated set of multiply-and-accumulate distribution data, and a target offset associated with a known set of multiply-and-accumulate distribution data that is obtained by performing a digital analog vector-matrix multiplication operation using the known input vectors and the target synaptic weight values of the synaptic weight matrix;
adjust one or more target bias weight values, which correspond to one or more stored bias weights of the given output line, to counteract the error between the determined offset and the target offset; and
reprogram the one or more stored bias weights of the given output line of the resistive processing unit array, based on the adjusted target bias weight values.

22. A method, comprising:
obtaining a matrix comprising target weight values;
programming an array of cells of a resistive processing unit array to store weight values which correspond to respective target weight values of the matrix; and
performing a calibration process to calibrate the resistive processing unit array, wherein the calibration process comprises iteratively adjusting the target weight values of the matrix, and reprogramming the stored weight values of the matrix in the resistive processing unit array based on the respective adjusted target weight values, to reduce a variation between output lines of the resistive processing unit array with respect to multiply-and-accumulate distribution data that is generated and output from respective output lines of the resistive processing unit array during the calibration process.

23. The method of claim 22, wherein performing the calibration process comprises:
converging respective offsets of the multiply-and-accumulate distribution data, which are output from respective output lines, to a target offset;
converging respective slopes of the multiply-and-accumulate distribution data, which are output from the respective output lines, to a target slope; and
iteratively adjusting one or more target bias weight values, which correspond to one or more stored bias weights of one or more of the output lines, and reprogramming the one or more stored bias weights of the one or more output lines, based on the adjusted target bias weight values, to reduce residual line-to-line offset variation.

24. A system, comprising:
a processor; and
a resistive processing unit array coupled to the processor, the resistive processing unit array comprising an array of cells, the cells respectively comprising resistive memory devices which are programable to store weight values;
wherein the processor is configured to:
obtain a matrix comprising target weight values;
program cells of the array of cells to store weight values, in the resistive processing unit array, which correspond to respective target weight values of the matrix; and
perform a calibration process to calibrate the resistive processing unit array, wherein calibration process comprises:
a first calibration process to iteratively adjust the target weight values of the matrix, and reprogram the stored weight values of the matrix in the resistive processing unit array based on the respective adjusted target weight values, to reduce an offset variation between output lines of the resistive processing unit array with respect to multiply-and-accumulate distribution data and to reduce a spread of the multiply-and-accumulate distribution data, which is generated and output from respective output lines of the resistive processing unit array during the first calibration process; and
a second calibration process, which is performed subsequent to the first calibration process, to scale the adjusted target weight values of the output lines, which exist at a completion of the first calibration process, by respective weight scaling factors, and reprogram the stored weight values of the output lines of the resistive processing unit array based on the scaled target weight values to reduce a slope variation between the output lines of the resistive processing unit array with respect to multiply-and-accumulate distribution data which is generated and output from the respective output lines of the resistive processing unit array.

25. The system of claim 24, wherein the calibration process further comprises a third calibration process, which is performed subsequent to the second calibration process, to iteratively adjust one or more target bias weight values, which correspond to one or more stored bias weights of one or more of the output lines, and reprogram the one or more stored bias weights of the one or more output lines, based on the adjusted target bias weight values, to reduce a residual offset variation between the output lines of the resistive processing unit array with respect to multiply-and-accumulate distribution data which is generated and output from respective output lines of the resistive processing unit array during the third calibration process, and wherein the obtained matrix comprises one of a computational matrix which is utilized to perform analog matrix computations for a linear system, and a trained synaptic weight matrix of a trained artificial neural network to perform inference processing.
